(19) United States
(12) Patent Application Publication
(10) Pub. No.: US 2026/0079832 A1
(43) Pub. Date: Mar. 19, 2026

(54) DATA DECOMPRESSION DEVICE, MEMORY SYSTEM, AND METHOD

(71) Applicant: Kioxia Corporation, Tokyo (JP)

(72) Inventors: Daisuke YASHIMA, Tokyo (JP); Sho KODAMA, Kamakura (JP); Keiri NAKANISHI, Kawasaki (JP)

(73) Assignee: Kioxia Corporation, Tokyo (JP)

(21) Appl. No.: 19/074,615

(22) Filed: Mar. 10, 2025

(30) Foreign Application Priority Data
Sep. 19, 2024 (JP) 2024-162205

(51) Int. Cl. G06F 12/02

(52) U.S. Cl. CPC G06F 12/0246

(57) ABSTRACT

According to one embodiment, a data decompression device decompresses a compressed data string obtained by dictionary-based compression, the compressed data string including first compressed data having a first offset. A dictionary circuit includes at least one first dictionary storing first decompressed data corresponding to the first compressed data, and at least one second dictionary storing the first decompressed data. An assignment circuit assigns the first compressed data to at least one dictionary of the at least one first dictionary or the at least one second dictionary.

### CROSS-REFERENCE TO RELATED APPLICATIONS

This application is based upon and claims the benefit of priority from Japanese Patent Application No. 2024-162205, filed Sep. 19, 2024, the entire contents of which are incorporated herein by reference.

### FIELD

Embodiments described herein relate generally to a data decompression device, a memory system, and a method.

### BACKGROUND

In recent years, the amount of data processed by information processing systems has increased. In order to reduce the amount of data to be stored, a dictionary-based compression device has been developed. One example of the dictionary-based compression device includes a dictionary-based compression device and an entropy coding circuit.

The dictionary-based compression device includes a dictionary (also referred to as a history buffer) which stores a history of past input data, that is, a history of uncompressed data, by a fixed size. The dictionary-based compression device generates information (referred to as a match length) indicating how long input data matches the uncompressed data at which storage location (referred to as an offset) of the dictionary. A pair of the offset and match length is referred to as match information. If the data size of the match information is expected to be smaller than that of the input data, the dictionary-based compression device replaces the input data with the match information. With this replacement, the dictionary-based compression device compresses the input data.

The entropy coding circuit uses a difference in occurrence frequency of match information to allocate code words of different code lengths to respective match information and thus compress data as a whole.

A data decompression device, which decompresses compressed data generated by the data compression device described above, includes an entropy decoding circuit and a dictionary-based decompression circuit.

The entropy decoding circuit decodes the compressed data to restore the match information. The dictionary-based decompression circuit includes a dictionary that stores decompressed data generated in the past. The dictionary-based decompression circuit refers to the dictionary based on the match information to generate decompressed data corresponding to a result of the decompression of the compressed data.

The data compression device is required to compress data at a high throughput. The data decompression device is required to decompress data at a high throughput. In order to increase the throughput of the dictionary-based decompression circuit, the dictionary-based decompression circuit needs to restore a plurality of items of match information in one clock cycle, that is, to refer to the dictionary a plurality of times in one cycle.

In dictionary-based compression, the minimum match length depends upon the compression algorithm. An example of the compression algorithm, gzip, has the minimum match length of 3 bytes. If the throughput required for the data decompression device is 4 bytes/cycle or more, the dictionary-based decompression circuit needs to restore a plurality of items of match information in one cycle and thus refers to a plurality of dictionaries simultaneously in one cycle.

### BRIEF DESCRIPTION OF THE DRAWINGS

FIG. 1 is a block diagram illustrating an example of an information processing system according to an embodiment.

FIG. 2 is a diagram illustrating an example of a compressed stream according to the embodiment.

FIG. 3 is a diagram illustrating an example of data generated in dictionary-based compression and data generated in entropy coding according to the embodiment.

FIG. 4 is a diagram illustrating an example of data generated in entropy decoding and data generated in dictionary-based decompression according to the embodiment.

FIG. 5 is a block diagram illustrating an example of a data compression device according to the embodiment.

FIG. 6 is a block diagram illustrating an example of a data decompression device according to the embodiment.

FIG. 7 is a block diagram illustrating an example of a dictionary-based decompression circuit according to the embodiment.

FIG. 8 is a flowchart illustrating an example of a process of the dictionary-based decompression circuit according to the embodiment.

FIG. 9 is a flowchart illustrating an example of a process of the dictionary-based decompression circuit according to the embodiment.

FIG. 10 is a flowchart illustrating an example of a process of the dictionary-based decompression circuit according to the embodiment.

FIG. 11 is a block diagram illustrating an example of a dictionary-based decompression circuit according to a comparative example.

FIG. 12 illustrates throughput satisfaction rates where a requested throughput is 2 bytes/cycle, 4 bytes/cycle, and 8 bytes/cycle.

FIG. 13 is a diagram illustrating an example of a dictionary including 1RW-SRAM according to the embodiment.

FIG. 14 is a diagram illustrating an example of reading the dictionary including 1RW-SRAM according to the embodiment.

FIG. 15 is a diagram illustrating an example of a dictionary including two 1RW-SRAMs according to the embodiment.

FIG. 16 is a diagram illustrating an example of a dictionary including 1R1W-SRAM according to the embodiment.

FIG. 17 is a diagram illustrating an example of a dictionary including 2RW-SRAM according to the embodiment.

FIG. 18 is a diagram illustrating an example of a dictionary including 2R1W-SRAM according to the embodiment.

FIG. 19 is a diagram illustrating another example of the dictionary including 2R1W-SRAM according to the embodiment.

FIG. 20 is a diagram illustrating yet another example of the dictionary including 2R1W-SRAM according to the embodiment.

FIG. 21 is a diagram illustrating yet another example of the dictionary including 2R1W-SRAM according to the embodiment.

FIG. 22 is a diagram illustrating yet another example of a dictionary according to the embodiment.

FIG. 23 is a diagram illustrating an example of write of a dictionary circuit according to the embodiment.

FIG. 24 is a diagram illustrating an example of read of a dictionary circuit according to the embodiment.

FIG. 25 is a diagram illustrating another example of write of a dictionary circuit according to the embodiment.

FIG. 26 is a flowchart illustrating an example of a process of a dictionary-based decompression circuit according to a modification.

### DETAILED DESCRIPTION

Embodiments will be described below with reference to the drawings. In the following descriptions, a device and a method are illustrated to embody the technical concept of the embodiments. The technical concept is not limited to the configuration, shape, arrangement, material or the like of the structural elements described below. Modifications that could easily be conceived by a person with ordinary skill in the art are naturally included in the scope of the disclosure. To make the descriptions clearer, the drawings may schematically show the size, thickness, planer dimension, shape, and the like of each element differently from those in the actual aspect. The drawings may include elements that differ in dimension and ratio. Elements corresponding to each other are denoted by the same reference numeral and their overlapping descriptions may be omitted. Some elements may be denoted by different names, and these names are merely an example. It should not be denied that one element is denoted by different names. Note that “connection” means that one element is connected to another element via still another element as well as that one element is directly connected to another element. If the number of elements is not specified as plural, the elements may be singular or plural.

In general, according to one embodiment, a data decompression device is configured to decompress a compressed data string obtained by dictionary-based compression, the compressed data string including first compressed data having a first offset. The data decompression device includes a dictionary circuit including at least one first dictionary configured to store first decompressed data corresponding to the first compressed data, and at least one second dictionary configured to store the first decompressed data; an assignment circuit configured to assign the first compressed data to at least one dictionary of the at least one first dictionary or the at least one second dictionary; a reference circuit configured to read, using the first offset, the first decompressed data from the at least one dictionary to which the first compressed data is assigned; and a generation circuit configured to generate a decompressed data string including the first decompressed data read by the reference circuit. A storage size of each of the at least one first dictionary is larger than a storage size of each of the at least one second dictionary. The first offset is configured to indicate a storage location of at least one dictionary of the at least one first dictionary or the at least one second dictionary. In a case where the compressed data string includes second compressed data having a second offset indicating a storage location of at least one dictionary of the at least one first dictionary or the at least one second dictionary; the assignment circuit is configured to assign, based on the first offset, the first compressed data to at least one dictionary of the at least one first dictionary or the at least one second dictionary, and assign, based on the second offset, the second compressed data to at least one dictionary of the at least one first dictionary or the at least one second dictionary, wherein the at least one dictionary to which the second compressed data is assigned is different from the at least one dictionary to which the first compressed data is assigned. The reference circuit is configured to perform a first read and a second read in parallel, wherein during the first read, the reference circuit is configured to read the first decompressed data using the first offset from the at least one dictionary to which the first compressed data is assigned, and during the second read, the reference circuit is configured to read the second decompressed data corresponding to the second decompressed data using the second offset from the at least one dictionary to which the second compressed data is assigned. The generation circuit is configured to generate the decompressed data string including the first decompressed data and the second decompressed data.

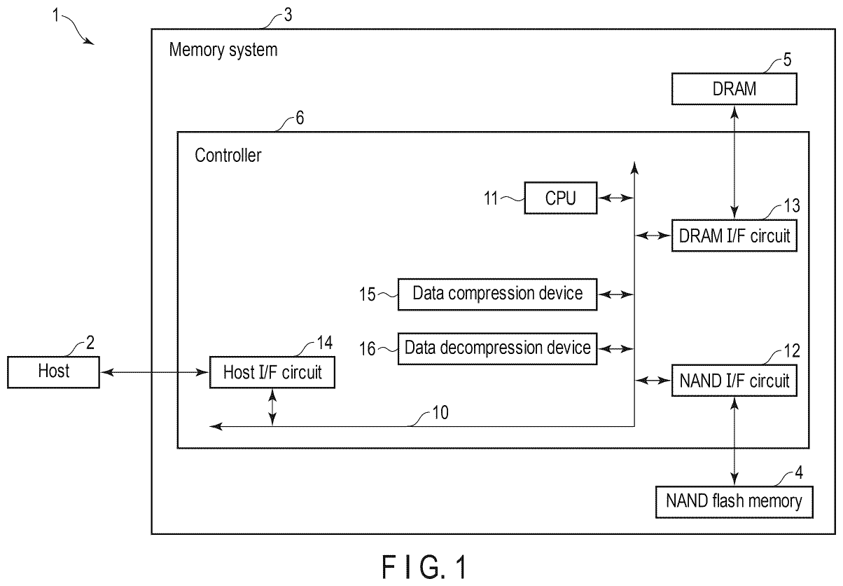

FIG. 1 is a block diagram illustrating an example of an information processing system 1. The information processing system 1 includes a data decompression device according to an embodiment. The information processing system 1 includes a host device 2 and a memory system 3. The host device 2 is referred to simply as the host 2.

The host 2 is an information processing device which writes data to the memory system 3 and reads data from the memory system 3. An example of the host 2 is a storage server or a personal computer which deals with a large amount of data and a variety of items of data.

The memory system 3 is a semiconductor storage device configured to write data to a nonvolatile memory and read data from the nonvolatile memory. An example of the nonvolatile memory is a NAND flash memory 4. The memory system 3 may be implemented as a solid state drive (SSD). A case in which the memory system 3 is implemented as an SSD will be described below. However, the memory system 3 may be implemented as a hard disk drive (HDD).

The memory system 3 can be used as a storage for the host 2. The memory system 3 may be built in the host 2. The memory system 3 may be coupled to the host 2 via a cable or network.

The interface for coupling the host 2 and the memory system 3 conforms to standards such as SCSI, Serial Attached SCSI (SAS), AT Attachment (ATA), Serial ATA (SATA), PCI Express™ (PCIe™), Ethernet™, Fiber channel, and NVM Express™ (NVMe™).

The memory system 3 may include the NAND flash memory 4, a dynamic random access memory (DRAM) 5, and a controller 6.

The NAND flash memory 4 includes one or more memory chips. Each of the memory chips includes a plurality of blocks. Each of the blocks serves as a unit of erase operation. The blocks may also be referred to as erase blocks or physical blocks. Each of the blocks includes a plurality of pages. Each of the pages includes a plurality of memory cells coupled to a single word line. One of the pages serves as a unit of write (or program) operation and read operation. Note that the word line may serve as the unit of write operation and read operation.

The number of program/erase cycles (P/E cycle number) for each block has the upper limit. The upper limit is referred to as the maximum P/E cycle number. One P/E cycle for a certain block includes an erase operation for erasing all memory cells in the block and a program operation for writing data to each of the pages of the block.

The DRAM 5 is a volatile memory. The storage area of the DRAM 5 is allocated as a variety of areas. Examples of the areas are a firmware storage area, a logical physical address translation table cache area, and a user data buffer area.

The controller 6 is a memory controller that controls the NAND flash memory 4 and the DRAM 5. The controller 6 may be implemented by, for example, a circuit such as a system-on-a-chip (SoC). The controller 6 may include a static random access memory (SRAM) or a DRAM. In this case, the DRAM 5 need not be provided outside the controller 6.

The controller 6 may function as a flash translation layer (FTL) configured to perform data management and block management for the NAND flash memory 4. Examples of data management performed by the FTL are (1) management of mapping information representing a correspondence between a logical address and a physical address of the NAND flash memory 4 and (2) processing for concealing a difference between a read/write operation per page and a data erase operation per block. Examples of the block management are management of defective blocks, wear leveling, and garbage collection.

The logical address is used by the host 2 to address the storage area of the memory system 3. An example of the logical address is a logical block address (LBA).

The management of mapping between logical and physical addresses may be performed using a logical-physical address translation table. The controller 6 uses the logical-physical address translation table to manage the mapping between logical and physical addresses in a specific management size unit. The physical address corresponding to a certain logical address indicates a physical storage location in the NAND flash memory 4. The user data of the certain logical address is written into the physical storage location. The logical-physical address translation table may be loaded from the NAND flash memory 4 into the DRAM 5 when the memory system 3 is started.

Data can be written to one page only once per P/E cycle. When a user data corresponding to a certain logical address is updated, the controller 6 does not write updated user data to a physical storage location in which pre-update user data is stored. The controller 6 writes the updated user data to a different physical storage location. The controller 6 updates the logical-physical address translation table to associate the certain logical address with the different physical storage location to invalidate the pre-update user data.

The controller 6 may include a CPU 11, a NAND interface (NAND I/F) circuit 12, a DRAM interface (DRAM I/F) circuit 13, a host interface (host I/F) circuit 14, a data compression device 15, and a data decompression device 16. The CPU 11, NAND I/F circuit 12, DRAM I/F circuit 13, host I/F circuit 14, data compression device 15, and data decompression device 16 may be coupled to each other via a bus 10.

The CPU 11 is a processor configured to control the NAND I/F circuit 12, DRAM I/F circuit 13, host I/F circuit 14, data compression device 15, and data decompression device 16. The CPU 11 executes the firmware loaded from the NAND flash memory 4 into the DRAM 5 to perform a variety of processes. The firmware is a control program including a group of instructions for causing the CPU 11 to perform a variety of processes. The CPU 11 performs a command process for processing a variety of commands from the host 2 in addition to the foregoing FTL process. The operation of the CPU 11 is controlled by firmware to be executed by the CPU 11. Some or all of the FTL and command processes may be performed by dedicated hardware within the controller 6.

The NAND I/F circuit 12 electrically couples the controller 6 and the NAND flash memory 4. The NAND I/F circuit 12 conforms to an interface standard such as a Toggle DDR interface and an Open NAND Flash interface (ONFI).

The NAND I/F circuit 12 functions as a NAND control circuit configured to control the NAND flash memory 4. The NAND I/F circuit 12 may be coupled to a plurality of memory chips in the NAND flash memory 4 via a plurality of channels. As the memory chips are driven in parallel, access to the entire NAND flash memory 4 can be broadened.

The DRAM I/F circuit 13 functions as a DRAM control circuit configured to control access to the DRAM 5.

The host I/F circuit 14 functions as an interface that performs communications between the memory system 3 and the host 2. The host I/F circuit 14 includes a circuit which receives various commands, such as an input/output (I/O) command and a control command, from the host 2. Examples of the I/O command are a write command or a read command. Examples of the control command are an un-map command (also referred to as a trim command) or a format command. The host I/F circuit 14 includes a circuit that supplies the host 2 with a response and data corresponding to a command.

The data compression device 15 encodes data to compress the data. An example of data to be compressed is data to be written to the NAND flash memory 4. Upon receipt of a write command from the host 2, the CPU 11 may input the received write data to the data compression device 15 as uncompressed data (also referred to as plain text data). The data compression device 15 encodes the uncompressed data input from the CPU 11 to generate a compressed stream (also referred to as compressed data).

The data compression device 15 may perform dictionary-based compression for each of a plurality of symbols included in the uncompressed data to acquire a plurality of compressed symbols. Hereinafter, a symbol acquired by dictionary-based compression will be referred to as a dictionary-compressed symbol. The data compression device 15 performs entropy coding for a plurality of dictionary-compressed symbols to generate a compressed stream including a plurality of variable-length code words.

The dictionary-based compression is encoding for converting uncompressed data as compression target data into match information using a dictionary that stores uncompressed data input in the past. The dictionary-based compression is also referred to as dictionary encoding. Examples of dictionary-based compression algorithms are LZ77 and LZSS. A dictionary is searched to acquire past data at least part of which coincides with uncompressed data to be compressed. Match information having an offset and a match length related to the acquired past data is generated. The offset indicates a distance from a location in the dictionary where the uncompressed data is stored to a location where the acquired past data is stored. The match length indicates the length of part of the past data which matches the uncompressed data. As the uncompressed data is converted into match information, the data is compressed. The match information will also be referred to as a match symbol or a dictionary match symbol.

If, as a result of the dictionary search, past data at least part of which matches the uncompressed data is not found, the uncompressed data (symbol) is output as it is. The uncompressed data that is not converted into a match symbol but is output as it is will be referred to as a literal symbol or a dictionary mismatch symbol.

Therefore, a plurality of dictionary-compressed symbols obtained by dictionary-based compression for a plurality of symbols included in uncompressed data include at least one of a match symbol or a literal symbol.

The entropy coding is variable-length coding in which a coding table is generated using the occurrence frequency of symbols to be encoded, such as dictionary-compressed symbols. The compression algorithm for use in the entropy coding may be an algorithm specified in DEFLATE. The coding table includes information representing a plurality of different symbols and information representing a plurality of code words associated with their respective symbols. In the entropy coding, a short code word is assigned to a symbol having a high occurrence frequency and a long code word is assigned to a symbol having a low occurrence frequency. In accordance with this assignment, an input symbol is converted into a code word. That is, the code word acquired by the conversion is a variable-length code word. Thus, the entropy coding can decrease the amount of data by utilizing a bias in the occurrence frequency of dictionary-compressed symbols. The compressed stream generated by the entropy coding includes a plurality of code words into which a plurality of dictionary-compressed symbols are respectively converted. The compressed stream may further include as a header data representing the coding table used for the entropy coding. The data representing the coding table is used to restore the coding table when the compressed stream is decompressed.

The data decompression device 16 decompresses the compressed stream by decoding. The compressed stream may be data read from the NAND flash memory 4. Upon receipt of a read command from the host 2, the CPU 11 may supply the data decompression device 16 with the compressed stream read from the NAND flash memory 4. The data decompression device 16 can also decode the compressed stream supplied from the CPU 11 to generate decompressed data.

The data decompression device 16 performs entropy decoding for each of the code words included in the compressed stream to acquire a plurality of dictionary-compressed symbols. The data decompression device 16 performs dictionary-based decompression for each of the dictionary-compressed symbols to generate decompressed data including a plurality of symbols, i.e., literal symbols.

The entropy decoding is to restore the coding table using data included in the header of the compressed stream and to convert a plurality of code words included in the compressed stream into a plurality of dictionary-compressed symbols on the basis of the coding table.

The dictionary-based decompression is decoding for converting match symbols included in a string of dictionary-compressed symbols to be decoded into decompressed data, that is, literal symbols, by utilizing a dictionary that stores decompressed data decoded and output in the past. The literal symbols included in the string of dictionary-compressed symbols are not dictionary-compressed but output as they are. The dictionary-based decompression is also referred to as dictionary-based decoding.

The memory system 3 has been described as including the DRAM 5. However, the memory system 3 may include a static random access memory (SRAM) as a volatile memory.

The controller 6 has been described as including the data compression device 15 and the data decompression device 16. However, the compression device 15 and the data decompression device 16 may be provided outside the controller 6 or outside the memory system 3.

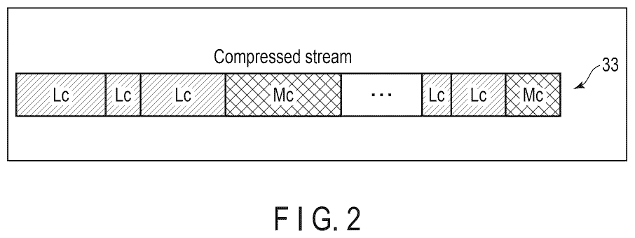

FIG. 2 is a diagram illustrating an example of a compressed stream 33 output from the data compression device 15 or a compressed stream 33 input to the data decompression device 16. The compressed stream 33 may include a code word Mc corresponding to a match symbol and a code word Lc corresponding to a literal symbol.

If at least some of the symbols included in the uncompressed data to be compressed are replaced by match symbols, the number of symbols of the compressed stream 33 becomes smaller than the number of symbols of a symbol string of the uncompressed data to be compressed, i.e., a symbol string which are all literal symbols.

The data compression device 15 may compress the uncompressed data in specific units. A specific unit of uncompressed data is also referred to as a Huffman block. The Huffman block has a specific data size. That is, the Huffman block includes a specific number of symbols. The specific data size can optionally be set in the information processing system 1, more specifically, in the data compression device 15 and the data decompression device 16. The data compression device 15 may select a coding table for use in the entropy coding for each Huffman block.

The data compression device 15 may add an End of Block (EOB) symbol to the end of each Huffman block so that the boundary of Huffman blocks can be detected. The EOB symbol indicates the end of a Huffman block. As an example of the EOB symbol, a bit string specified by DEFLATE may be used. The data decompression device 16 may select a coding table for use in the entropy decoding in accordance with the detection of an EOB symbol.

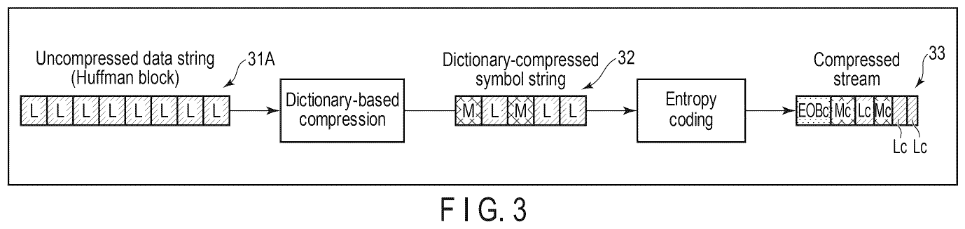

FIG. 3 is a diagram illustrating an example of data generated in dictionary-based compression and data generated in entropy coding by the data compression device 15. Assume here that an uncompressed data string 31A corresponds to a Huffman block.

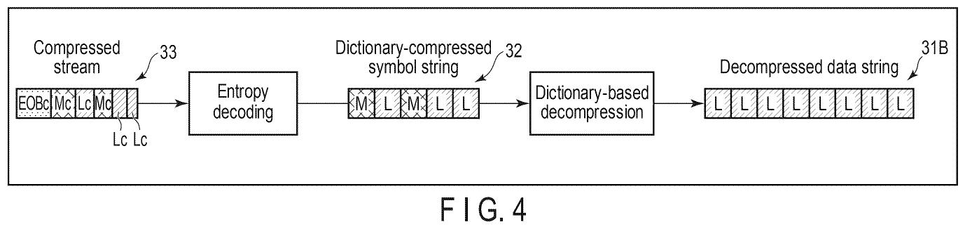

FIG. 4 is a diagram illustrating an example of data generated in entropy decoding and data generated in dictionary-based decompression by the data decompression device 16. The data decompression device 16 decompresses the compressed stream 33 for each Huffman block.

As illustrated in FIG. 3, the uncompressed data string 31A input to the data compression device 15, that is, one Huffman block, is converted into a dictionary-compressed symbol string 32 by dictionary-based compression. The uncompressed data string 31A may include a plurality of literal symbols L as uncompressed data. The dictionary-compressed symbol string 32 may include a plurality of dictionary-compressed symbols. In the uncompressed data string 31A, a byte string that matches at least part of a byte string in the dictionary that is a past byte string, is replaced by match symbols M and output as dictionary-compressed symbols. In the uncompressed data string 31A, a byte string for which no matching past byte string is found, is output as an uncompressed byte string, that is, as dictionary-compressed symbols that are literal symbols L. The dictionary-compressed symbol string 32 may include only literal symbols L and may not include match symbols M. The dictionary-compressed symbol string 32 may include only match symbols M and may not include literal symbols L.

In the example shown in FIG. 3, eight literal symbols L included in the uncompressed data string 31A are converted into a dictionary-compressed symbol string 32 including five dictionary-compressed symbols by a dictionary-based compression circuit. The dictionary-compressed symbol string 32 includes two match symbols M and three literal symbols L. In this manner, the uncompressed data string 31A can be compressed into the dictionary-compressed symbol string 32 in which the number of symbols is reduced by dictionary-based compression.

Then, an EOB symbol is added to the end of the dictionary-compressed symbol string 32. The dictionary-compressed symbol string 32 and EOB symbol are converted into a compressed stream 33 by entropy coding. Specifically, the dictionary-compressed symbol string 32 and EOB symbol are converted into variable-length code words for each symbol by entropy coding.

In the example shown in FIG. 3, the compressed stream 33 includes three variable-length code words Lc obtained by entropy coding each of the three literal symbols L, two variable-length code words Mc obtained by entropy coding each of two match symbols M, and a variable-length code word EOBc obtained by entropy coding the EOB symbol. The “entropy coding” is coding dictionary-compressed symbols with the number of codes corresponding to the frequency of occurrence. The dictionary-compressed symbol string 32 is compressed into the compressed stream 33 in which the amount of data is reduced by entropy coding. That is, the compressed stream 33 is data obtained by compressing the uncompressed data string 31A, in this case, one Huffman block, by dictionary-based compression and entropy coding. Even if the dictionary-compressed symbol string 32 consists only of literal symbols L, the entropy coding can reduce the amount of data.

As described above, the EOB symbol can be used to detect the boundary of the Huffman blocks during decoding by the data decompression device 16. Upon detection of the boundary of the Huffman blocks, the data decompression device 16 selects a coding table for use in decoding.

As shown in FIG. 4, the compressed stream 33 input to the data decompression device 16 is converted into a dictionary-compressed symbol string 32 by entropy decoding. Specifically, a plurality of variable-length code words included in the compressed stream 33 are converted into a dictionary-compressed symbol string 32 and an EOB symbol by entropy decoding. As the EOB symbol is obtained, the boundary of the Huffman block in the compressed stream 33 is detected. The EOB symbol is excluded from the dictionary-compressed symbol string 32.

In the example shown in FIG. 4, the variable-length code word EOBc included in the compressed stream 33 is entropy decoded to acquire the EOB symbol. The two variable-length code words Mc included in the compressed stream 33 are entropy decoded to acquire two match symbols M. The three variable-length code words Lc included in the compressed stream 33 are entropy decoded to acquire three literal symbols L. The three literal symbols L and two match symbols M are output as a dictionary-compressed symbol string 32 according to the order of decoding.

Then, the dictionary-compressed symbol string 32 is converted into the decompressed data string 31B by dictionary-based decompression. Specifically, the match symbols M in the dictionary-compressed symbol string 32 is replaced with the past byte string indicated by match information, for example, a byte string in the dictionary. The match symbols M are output as the decompressed data string 31B. On the other hand, the literal symbols L in the dictionary-compressed symbol string 32 are a decompressed byte string. The literal symbols L are output as the decompressed data string 31B. That is, the decompressed data string 31B is data obtained by decompressing the compressed stream 33, in this case, the compressed data corresponding to one Huffman block, by entropy decoding and dictionary-based decompression. The decompressed data string 31B corresponds to the uncompressed data string 31A.

In the example shown in FIG. 4, five dictionary-compressed symbols M and L included in the dictionary-compressed symbol string 32 are converted into the decompressed data string 31B including eight symbols, i.e., eight literal symbols L, by dictionary-based decompression. In this manner, the dictionary-compressed symbol string 32 can be decompressed by dictionary-based decompression into the decompressed data string 31B whose symbols are increased in number. That is, the decompressed data string 31B is a data string obtained by decompressing the compressed stream 33 by entropy decoding and dictionary-based decompression.

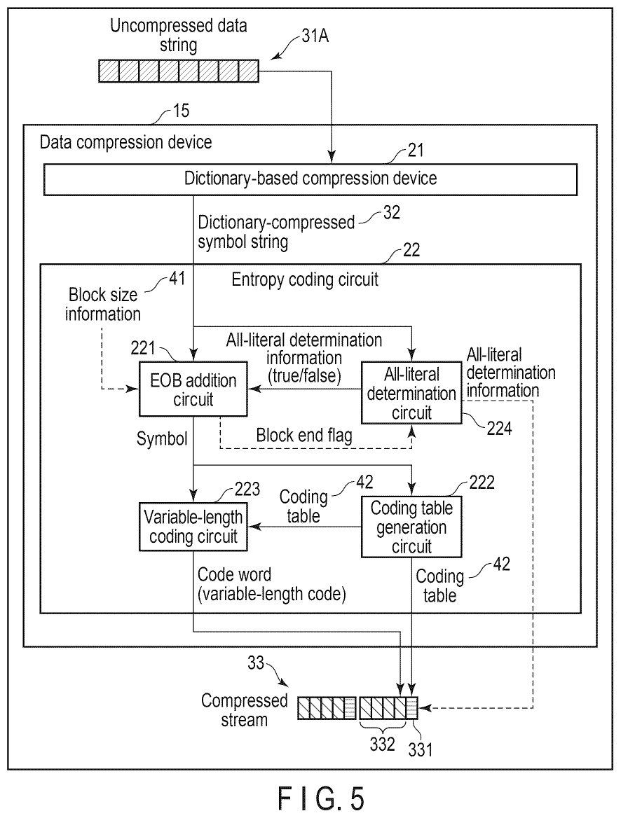

FIG. 5 is a block diagram illustrating an example of the data compression device 15.

The data compression device 15 compresses the uncompressed data string 31A into a compressed stream 33 by dictionary-based compression and entropy coding. An example of the uncompressed data string 31A is data to be compressed which includes one or more Huffman blocks. The data compression device 15 includes a dictionary-based compression device 21 and an entropy coding circuit 22.

The dictionary-based compression device 21 converts the uncompressed data string 31A into a dictionary-compressed symbol string 32 by dictionary-based compression. The dictionary-compressed symbol string 32 may include a literal symbol L and a match symbol M. The dictionary-based compression device 21 transmits the dictionary-compressed symbol string 32 to the entropy coding circuit 22.

The entropy coding circuit 22 converts the dictionary-compressed symbol string 32 into variable-length code words by entropy coding to generate a compressed stream 33. The entropy coding circuit 22 may include an all-literal determination circuit 224, an EOB addition circuit 221, a coding table generation circuit 222, and a variable-length coding circuit 223.

The dictionary-based compression device 21, EOB addition circuit 221, coding table generation circuit 222, variable-length coding circuit 223, and all-literal determination circuit 224 are each implemented by at least one of a register, an adder, a multiplier, a selector, or another computing unit. The register is implemented by a logic circuit such as a flip-flop. The adder, multiplier, selector, and computing unit are implemented by logic circuits.

The all-literal determination circuit 224 determines whether all of one or more dictionary-compressed symbols included in the dictionary-compressed symbol string 32 are literal symbols L or not. The dictionary-compressed symbol string 32 are received successively from the dictionary-based compression device 21 after a first timing. At the first timing, the data compression device 15 starts a data compression process or the EOB addition circuit 221 notifies the end of a Huffman block. The end of a Huffman block is notified when a block end flag as described later is received. The dictionary-compressed symbol string 32 includes one or more dictionary-compressed symbols included in a data block (referred to as a second data block). The second data block is obtained by dictionary-based compression for one Huffman block (referred to as a first data block). The all-literal determination circuit 224 may determine whether all of one or more symbols in the dictionary-compressed symbol string 32 are literal symbols L based on whether the byte value of each of the symbols included in the dictionary-compressed symbol string 32 matches the byte value of any of the predefined literal symbols L. An example of the predefined byte value may be a byte value specified by DEFLATE.

The all-literal determination circuit 224 transmits to the EOB addition circuit 221 information (referred to as all-literal determination information) indicating whether the dictionary-compressed symbol string 32 contains only the literal symbols L, i.e., it does not contain the match symbol M. An example of the all-literal determination information is information indicating either true or false. As a value indicating true, “1” may be used. As a value indicating false, “0” may be used. Specifically, the all-literal determination circuit 224 transmits a signal including all-literal determination information to the EOB addition circuit 221 at all times or every fixed time.

The EOB addition circuit 221 transmits a block end flag to the all-literal determination circuit 224. The block end flag is information indicating the end of the Huffman block. This information indicates that the end of a dictionary-compressed symbol string 32 to be determined corresponds to the end of a Huffman block. When the EOB addition circuit 221 transmits the block end flag, the all-literal determination circuit 224 may output the current all-literal determination information as a header section 331. The all-literal determination information may be used in the data decompression device 16 to determine whether a Huffman block corresponding to the dictionary-compressed symbol stream 32 obtained by entropy decoding for the compressed stream 33 is one including only the literal symbol L and not including the match symbol M.

If the all-literal determination information indicates “false”, the EOB addition circuit 221 adds an EOB symbol to the end of at least one dictionary-compressed symbol corresponding to one Huffman block.

Specifically, each time the EOB addition circuit 221 receives one dictionary-compressed symbol from the dictionary-based compression device 21, the EOB addition circuit 221 may acquire the data size of the dictionary-compressed symbol which is not dictionary-compressed yet to calculate the cumulative value of the acquired data size, that is, the size of the uncompressed data. If the dictionary-compressed symbol is a literal symbol L, an example of the data size of the dictionary-compressed symbol which is not dictionary-compressed yet is one byte. If the dictionary-compressed symbol is a match symbol M, the data size of the dictionary-compressed symbol which is not dictionary-compressed yet may be a match length in bytes represented by the match symbol M. The EOB addition circuit 221 transmits the dictionary-compressed symbol whose data size is obtained, to the coding table generation circuit 222 and the variable-length coding circuit 223.

Based on the calculated uncompressed data size and block size information 41, the EOB addition circuit 221 determines whether the end of at least one dictionary-compressed symbol used for calculating the uncompressed data size corresponds to the end of the Huffman block. The block size information 41 indicates the block size of one Huffman block. The block size information 41 may be generated based on the block size specified in the information processing system 1. The block size information 41 may be stored in an optional area in the data compression device 15 or the memory system 3. The block size information 41 may be received from an external device, for example, the host 2. Based on whether the calculated uncompressed data size has reached the block size, the EOB addition circuit 221 determines whether the end of at least one dictionary-compressed symbol corresponds to the end of the Huffman block. The symbol of the end of at least one dictionary-compressed symbol is a symbol whose data size was acquired just before or acquired at the latest.

When the calculated uncompressed data size reaches the block size, that is, when the end of at least one dictionary-compressed symbol corresponds to the end of the Huffman block, the EOB addition circuit 221 determines whether the all-literal determination information received from the all-literal determination circuit 224 indicates true or false.

If the all-literal determination information indicates false, the EOB addition circuit 221 adds an EOB symbol to the end of the current Huffman block. That is, the EOB addition circuit 221 transmits an EOB symbol to the coding table generation circuit 222 and the variable-length coding circuit 223. The transmitted EOB symbol is located after the dictionary-compressed symbol 32 whose data size was acquired just before.

On the other hand, if the all-literal determination information indicates true, the EOB addition circuit 221 adds no EOB symbol to the end of the current Huffman block. That is, the EOB addition circuit 221 transmits no EOB symbol to the coding table generation circuit 222 or the variable-length coding circuit 223. Therefore, no EOB symbol is located after the dictionary-compressed symbol whose data size was acquired just before.

The EOB addition circuit 221 transmits to the all-literal determination circuit 224 information (referred to as a block end flag) which indicates that the end of at least one dictionary-compressed symbol used to calculate the uncompressed data size corresponds to the end of the Huffman block. The EOB addition circuit 221 may transmit a block end flag to the coding table generation circuit 222.

The coding table generation circuit 222 generates a coding table 42 based on the frequency of occurrence of each of a plurality of symbols corresponding to one Huffman block. The symbols corresponding to one Huffman block may include symbols received from the EOB addition circuit 221 from the first timing until the block end flag is received. Specifically, the coding table generation circuit 222 assigns a short code word to a symbol with a high occurrence frequency and assigns a long code word to a symbol with a low occurrence frequency. The coding table generation circuit 222 transmits the generated coding table 42 to the variable-length coding circuit 223. The coding table generation circuit 222 outputs data representing the coding table 42 as the header section 331 of the compressed stream 33.

The variable-length coding circuit 223 generates a plurality of variable-length code words corresponding to their respective symbols corresponding to one Huffman block by variable-length coding. Specifically, based on the coding table 42, the variable-length coding circuit 223 converts a plurality of symbols corresponding to one Huffman block into a plurality of variable-length code words. The variable-length coding circuit 223 sequentially outputs the variable-length code words into which the symbols are converted, as a payload section 332 of the compressed stream 33. If an EOB symbol is added by the EOB addition circuit 221, the payload section 332 includes one or more variable-length code words corresponding to one or more dictionary-compressed symbols and an end variable-length code word corresponding to the EOB block. If no EOB symbol is added by the EOB addition circuit 221, the payload section 332 includes a plurality of variable-length code words corresponding to a plurality of dictionary-compressed symbols all of which are literal symbols L.

Upon receiving a plurality of symbols corresponding to the next Huffman block from the EOB addition circuit 221, the coding table generation circuit 222 generates a new coding table 42 and transmits it to the variable-length coding circuit 223. The variable-length coding circuit 223 uses the new coding table 42 to convert the symbols corresponding to the Huffman block into a plurality of variable-length code words.

Thus, the compressed stream 33 includes a header section 331 and a payload section 332 for each Huffman block. The header section 331 includes the coding table 42. The payload section 332 includes either a variable-length code word string “A” or a variable-length code word string “B”. The variable-length code word string “A” is obtained by variable-length coding a dictionary-compressed symbol string 32 and an EOB symbol. The variable-length code word string “B” is obtained by variable-length coding a dictionary-compressed symbol string 32 all of which are literal symbols L.

If the payload section 332 includes the variable-length code word string “B”, the header section 331 may further include information (referred to as compression size information) indicating the size of the variable-length code word string. The size of the variable-length code word string included in the payload section 332 is the size of the variable-length code word string obtained by dictionary-based compression and entropy coding for the corresponding Huffman block, that is, the size of the compressed Huffman block. The compression size information may be used in the data decompression device 16 to determine whether the end of one or more variable-length code words in the compressed stream 33 corresponds to the end of the Huffman block when one or more symbols are obtained by entropy decoding of the one or more variable-length code words. That is, the compression size information is used to determine the boundary between Huffman blocks.

With the foregoing configuration, the data compression device 15 can compress the uncompressed data string 31A into the compressed stream 33 by dictionary-based compression and entropy coding. If no EOB symbol is added when one or more dictionary-compressed symbols obtained by dictionary-based compression for the Huffman block are all literal symbols L, the data compression device 15 can improve compression efficiency and coding throughput. If an EOB symbol is added when at least one of the dictionary-compressed symbols obtained by dictionary-based compression for the Huffman block is not a literal symbol L, the data compression device 15 can avoid decreasing throughput during decoding.

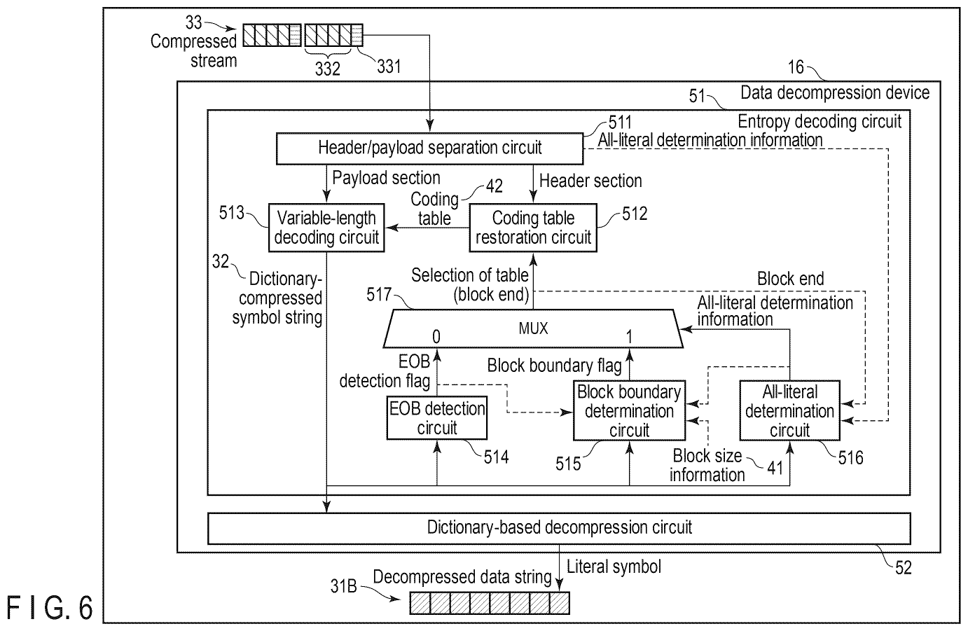

FIG. 6 is a block diagram illustrating an example of the data decompression device 16. The data decompression device 16 decompresses the compressed stream 33 into the decompressed data string 31B by entropy decoding and dictionary-based decompression. The compressed stream 33 is data to be decompressed which corresponds to one or more Huffman blocks. The data decompression device 16 includes an entropy decoding circuit 51 and a dictionary-based decompression circuit 52.

The entropy decoding circuit 51 generates a dictionary-compressed symbol string 32 from the compressed stream 33 by entropy decoding. An example of the entropy decoding circuit 51 includes a header/payload separation circuit 511, a coding table restoration circuit 512, a variable-length decoding circuit 513, an EOB detection circuit 514, a block boundary determination circuit 515, an all-literal determination circuit 516, and a multiplexer (MUX) 517.

The dictionary-based decompression circuit 52, header/payload separation circuit 511, coding table restoration circuit 512, variable-length decoding circuit 513, EOB detection circuit 514, block boundary determination circuit 515, all-literal determination circuit 516, and multiplexer 517 each may be implemented by at least one of a register, an adder, a multiplier, a selector, or another computing unit. The register may be implemented by a logic circuit such as a flip-flop. The adder, multiplier, selector, and computing unit may be implemented by logic circuits.

The header/payload separation circuit 511 separates the header section 331 and the payload section 332 from the compressed stream 33. The header/payload separation circuit 511 transmits the header section 331 to the coding table restoration circuit 512. The header/payload separation circuit 511 transmits the payload section 332 subsequent to the header section 331 to the variable-length decoding circuit 513. If the header section 331 includes all-literal determination information, the header/payload separation circuit 511 may transmit the all-literal determination information to the all-literal determination circuit 516.

The coding table restoration circuit 512 restores the coding table 42 using data included in the header section 331. The coding table restoration circuit 512 transmits the restored coding table 42 to the variable-length decoding circuit 513.

The variable-length decoding circuit 513 generates a plurality of symbols corresponding to a plurality of variable-length code words included in the payload section 332 by variable-length decoding. Specifically, the variable-length decoding circuit 513 converts the variable-length code words into a plurality of symbols based on the coding table 42. The symbols obtained by the conversion are dictionary-compressed symbols or EOB symbols. The variable-length decoding circuit 513 sequentially transmits the generated symbols to the EOB detection circuit 514, block boundary determination circuit 515, all-literal determination circuit 516, and dictionary-based decompression circuit 52.

The EOB detection circuit 514 detects an EOB symbol from the symbols received from the variable-length decoding circuit 513. The EOB detection circuit 514 transmits information indicating that the EOB symbol has been detected to the multiplexer 517 and the block boundary determination circuit 515. The information is referred to as an EOB detection flag.

Specifically, each time the EOB detection circuit 514 receives a symbol from the variable-length decoding circuit 513, the EOB detection circuit 514 determines whether the symbol matches the EOB symbol. When receiving one or more symbols from the variable-length decoding circuit 513, the EOB detection circuit 514 may determine whether the symbols match the EOB symbol (more specifically, the value assigned to the EOB symbol) in order from the first one. When no EOB symbol is detected from the first symbol to the symbol one before the latest symbol, the EOB detection circuit 514 determines whether the latest symbol matches the EOB symbol. When the latest symbol matches the EOB symbol, the EOB detection circuit 514 detects the latest symbol as an EOB symbol. Thus, the EOB detection circuit 514 detects that the end of at least one symbol corresponds to that of the Huffman block. The EOB detection circuit 514 transmits an EOB detection flag to the multiplexer 517 and the block boundary determination circuit 515. The EOB detection flag indicates that the end of at least one symbol corresponds to the end of the Huffman block.

The block boundary determination circuit 515 transmits to the multiplexer 517 information. The information indicates that the end of at least one symbol received successively from the variable-length decoding circuit 513 after a second timing corresponds to that of the Huffman block, that is, a block boundary flag. At the second timing, the data decompression device 16 starts a data decompression process or the data decompression device 16 receives an EOB detection flag from the EOB detection circuit 514.

Specifically, each time the block boundary determination circuit 515 receives a symbol from the variable-length decoding circuit 513, the block boundary determination circuit 515 acquires a data size of the symbol that is dictionary-decompressed and calculates a cumulative value of the acquired data size, that is, a decompressed data size. Assuming that the received symbol is a literal symbol L, the block boundary determination circuit 515 acquires a data size of the symbol that is dictionary-decompressed. The literal symbol L is a symbol that is not dictionary-compressed. An example of the data size of the literal symbol L that is dictionary-decompressed is one byte. Therefore, assuming that symbols received from the variable-length decoding circuit 513 are literal symbols L, the block boundary determination circuit 515 can easily calculate the decompressed data size by counting the number of received symbols.

Based on the calculated decompressed data size and the block size information 41, the block boundary determination circuit 515 determines whether the end of at least one symbol used for calculating the decompressed data size corresponds to the end of the Huffman block. The block size information 41 may be stored in an optional area in the data decompression device 16 or the memory system 3. The block size information 41 may be received from an external device, for example, the host 2. Specifically, the block boundary determination circuit 515 determines that the end of at least one symbol corresponds to the end of the Huffman block in accordance with the fact that the calculated decompressed data size has reached the block size. The symbol whose data size has just been calculated corresponds to the end of one Huffman block. The block boundary determination circuit 515 can thus detect a boundary between the Huffman blocks. In response to the detection of the boundary, the block boundary determination circuit 515 transmits a block boundary flag to the multiplexer 517. An example of the block boundary flag is a signal indicating that a boundary between Huffman blocks is detected, that is, that the end of at least one symbol corresponds to the end of each of the Huffman blocks.

The all-literal determination circuit 516 transmits to the multiplexer 517 and the block boundary determination circuit 515 all-literal determination information indicating whether one or more symbols (also referred to as target symbols) successively received from the variable-length decoding circuit 513 after a third timing are all-literal symbols L. At the third timing, the data decompression device 16 starts a data decompression process or the multiplexer 517 notifies the all-literal determination circuit 516 of the end of the Huffman block. The all-literal determination circuit 516 may determine whether a symbol string to be determined includes only the literal symbols L, that is, whether the symbol string to be determined includes no match symbol M, based on whether the byte value of each of the symbols included in the symbol string to be determined matches the byte value of one of the literal symbols L specified in advance, for example, by DEFLATE.

The all-literal determination circuit 516 may use the all-literal determination information received from the header/payload separation circuit 511, that is, the all-literal determination information in the header section 331, to determine whether a symbol string to be determined includes only the literal symbols L. In this case, the circuit scale of the all-literal determination circuit 516, that is, the amount of computation can be reduced.

The all-literal determination circuit 516 transmits all-literal determination information to the multiplexer 517 and the block boundary determination circuit 515 at all times or every fixed time. The all-literal determination process to be performed by the all-literal determination circuit 516 is almost the same as the all-literal determination process to be performed by the all-literal determination circuit 224 of the data compression device 15. More specifically, the all-literal determination process to be performed by the all-literal determination circuit 516 corresponds to a process in which the dictionary-based compression device 21 and EOB addition circuit 221 in the above-described all-literal determination process are replaced by the variable-length decoding circuit 513 and the multiplexer 517, respectively. The variable-length decoding circuit 513 transmits a symbol to the all-literal determination circuit 516. The multiplexer 517 notifies the end of the Huffman block.

The multiplexer 517 is a selector which outputs either the EOB detection flag output by the EOB detection circuit 514 or the block boundary flag output by the block boundary determination circuit 515 according to whether the all-literal determination information is true or false. In the example of the multiplexer 517 shown in FIG. 6, all-literal determination information which is true is represented as “1”. All-literal determination information which is false is represented as “0”. Specifically, if the multiplexer 517 receives the EOB detection flag from the EOB detection circuit 514 while receiving the all-literal determination information indicating false (“0” in FIG. 6) from the all-literal determination circuit 516, the multiplexer 517 notifies the coding table restoration circuit 512 of the selection of the coding table 42 and notifies the all-literal determination circuit 516 of the end of the current Huffman block, based on the EOB detection flag. On the other hand, if the multiplexer 517 receives the block boundary flag from the block boundary determination circuit 515 while receiving all-literal determination information indicating true (“1” in FIG. 6) from the all-literal determination circuit 516, the multiplexer 517 notifies the coding table restoration circuit 512 of the selection of the coding table 42 and notifies the all-literal determination circuit 516 of the end of the current Huffman block, based on the block boundary flag. Specifically, in order to notify the coding table restoration circuit 512 of the selection of the coding table 42, the multiplexer 517 may transmit a signal indicating the selection of the coding table 42 to the coding table restoration circuit 512. In order to notify the coding table restoration circuit 512 of the end of the current Huffman block, the multiplexer 517 may transmit a signal indicating the end of the current Huffman block to the all-literal determination circuit 516.

Upon receiving the notification of the selection of the coding table 42 from the multiplexer 517, the coding table restoration circuit 512 restores a new coding table 42 using data included in the next header section received from the header/payload separation circuit 511. The variable-length decoding circuit 513 uses the new coding table 42 to convert a plurality of variable-length code words included in the subsequent payload section into a dictionary-compressed symbol string 32.

The dictionary-based decompression circuit 52 generates by dictionary-based decompression the decompressed data string 31B from the dictionary-compressed symbol string 32 received from the variable-length decoding circuit 513. Specifically, if the dictionary-compressed symbol is a match symbol M, the dictionary-based decompression circuit 52 outputs as the decompressed data string 31B the past byte string in the dictionary indicated by the match information. If the dictionary-compressed symbol is a literal symbol L, the dictionary-based decompression circuit 52 outputs the literal symbol L as the decompressed data string 31B. The dictionary-based decompression circuit 52 does not output the EOB symbol received from the variable-length decoding circuit 513 as the decompressed data string 31B.

With the foregoing configuration, if all of the variable-length decoded dictionary-compressed symbols corresponding to the Huffman blocks are literal symbols L, the data decompression device 16 can detect the end of each of the Huffman blocks based on the number of dictionary-compressed symbols obtained from the variable-length decoding circuit 513. In this case, the data decompression device 16 does not need to perform a process of decoding the EOB symbol or to calculate the decompressed data size according to the type of symbols obtained by variable-length decoding. The data decompression device 16 can thus improve the throughput of decoding. Furthermore, no EOB symbol is added to the Huffman block in which all of the corresponding dictionary-compressed symbols are literal symbols L. Therefore, the compressed stream 33 to be input is data with high compression efficiency.

Note that the block boundary determination circuit 515 may use the compression size information to determine whether the end of at least one dictionary-compressed symbols successively received from the variable-length decoding circuit 513 after the second timing corresponds to the end of the Huffman block. The compression size information is information indicating the size of a data block, more specifically, a variable-length code word string, which is obtained by dictionary-based compression and entropy coding for the corresponding Huffman block. The compression size information is acquired from the header section 331. Note that the compression size information representing a specific size may be stored in advance in the data decompression device 16.

Specifically, the block boundary determination circuit 515 calculates a data size (referred to as a compressed data size) of at least one variable-length code corresponding to at least one symbol received from the variable-length decoding circuit 513. Each time the block boundary determination circuit 515 receives a symbol from the variable-length decoding circuit 513, the block boundary determination circuit 515 may acquire the data size of the symbol using the coding table 42. The acquired data size is a size of the symbol which has not been variable-length decoded, for example, the code length of the corresponding variable-length code word. The block boundary determination circuit 515 may then calculate the cumulative value of the acquired data size as a compressed data size.

If all of the received symbols are literal symbols L, the block boundary determination circuit 515 may transmit to the multiplexer 517 information (block boundary flag) indicating that the end of at least one symbol used for calculating the compressed data size corresponds to the end of the Huffman block, based on the calculated compressed data size and the compressed size information. More specifically, the block boundary determination circuit 515 transmits a block boundary flag to the multiplexer 517 if the all-literal determination information received from the all-literal determination circuit 516 indicates true and the calculated compressed data size is equal to the size indicated in the compressed size information. Even when the boundary between Huffman blocks is determined using the compression size information, the same advantageous effect as in the block boundary determination process described above can be obtained.

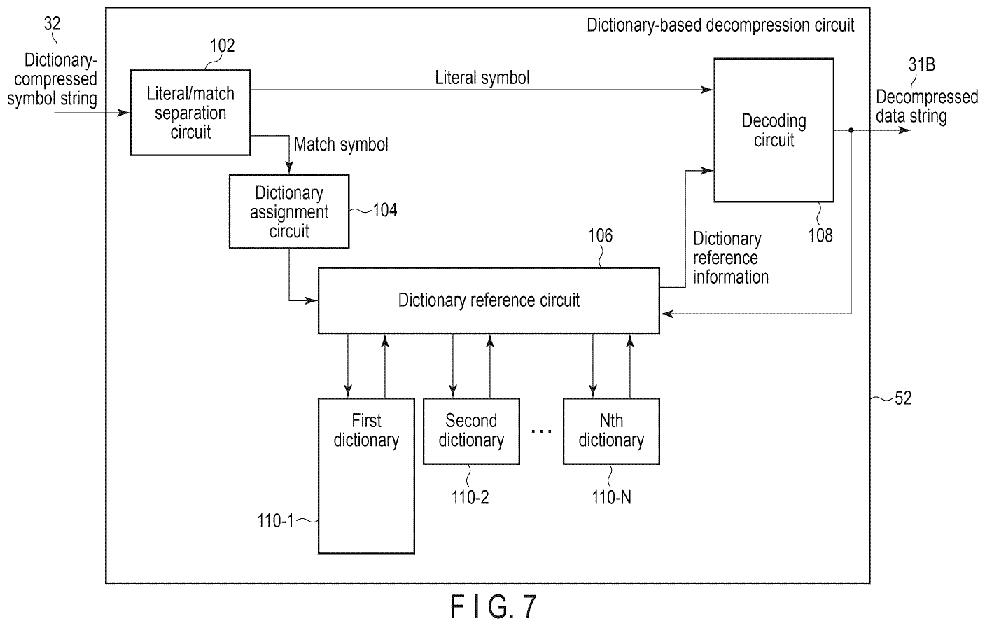

FIG. 7 is a block diagram illustrating an example of the dictionary-based decompression circuit 52. The dictionary-based decompression circuit 52 includes a literal/match separation circuit 102, a dictionary assignment circuit 104, a dictionary reference circuit 106, a decoding circuit 108, and a dictionary 110.

The dictionary 110 includes a plurality of dictionaries (first dictionary 110-1, second dictionary 110-2, . . . , and Nth dictionary 110-N, wherein N is a positive integer of two or more). Each of the dictionaries 110-1 to 110-N includes a memory. An example of the memory is a static random access memory (SRAM). The dictionaries 110-1 to 110-N are coupled in parallel to the dictionary reference circuit 106. The dictionaries 110-1 to 110-N can be simultaneously referred to from the dictionary reference circuit 106. The “simultaneously referred” means that data readings from the first dictionary 110-1, second dictionary 110-2, . . . , and Nth dictionary 110-N can be executed in parallel.

The first dictionary 110-1 to the Nth dictionary 110-N are classified into two types of dictionary according to the storage size. The storage size of each of the first dictionary 110-1 to Nth dictionary 110-N is one of two different sizes. The storage size of at least one dictionary is a first size. The first size depends upon the maximum value of the offset determined by the compression/decompression algorithm. The first size is also referred to as a full size. The storage size of each of the remaining dictionaries is an optional second size. The second size is smaller than the first size. In one example, the storage size of the first dictionary 110-1 is the first size. The first dictionary 110-1 is classified as a first type of dictionary. The first dictionary 110-1 is also referred to as a full-size dictionary. The storage size of each of the second dictionary 110-2 to the Nth dictionary 110-N is the second size. Each of the second dictionary 110-2 to the Nth dictionary 110-N is classified as a second type of dictionary. If the distribution trend of the offset is known in advance as the trend of input data, the second size may be designed in accordance with the trend.

At least one item of decompressed data, that is, at least one literal symbol, which is included in the decompressed data string 31B output from the decoding circuit 108, is written to the first dictionary 110-1 to the Nth dictionary 110-N. A literal symbol is written to each of the first dictionary 110-1 to Nth dictionary 110-N to increase the address from the head of a free area. The maximum address value of the first dictionary 110-1 is larger than that of each of the second to Nth dictionaries 110-2 to 110-N. After a literal symbol is written to each of the first dictionary 110-1 to Nth dictionary 110-N up to the maximum address value, the address pointer is returned to 0, and a new literal symbol is written thereto from the initial address. That is, the literal symbols stored in the dictionaries 110-1 to 110-N are rewritten by new literal ones.

As described above, at least one literal symbol output in the past first period starting from the present is stored in each of the first dictionary 110-1 to Nth dictionary 110-N. The first period is the latest period. The storage size of each of the second to Nth dictionaries 110-2 to 110-N, i.e., the maximum address value, is smaller than that of the first dictionary 110-1. Therefore, at least one literal symbol output in a second period prior to the first period is stored in none of the second to Nth dictionaries 110-2 to 110-N, but is stored only in the first dictionary 110-1. The second to Nth dictionaries 110-2 to 110-N each store only at least one literal symbol output in the first period. Therefore, the dictionaries 110-2 to 110-N are referred to as neighborhood dictionaries. The full-size dictionary (first dictionary) 110-1 stores at least one literal symbol output in the first period and at least one literal symbol output in the second period.

The dictionary-compressed symbol string 32 output from the entropy decoding circuit 51 is input to the literal/match separation circuit 102. The dictionary-compressed symbol string 32 input to the dictionary-based decompression circuit 52 in one cycle includes a plurality of dictionary-compressed symbols. The one cycle refers to one cycle of a clock as a reference for the operation of the dictionary-based decompression circuit 52. Each of the dictionary-compressed symbols included in the dictionary-compressed symbol string 32 of one cycle is a match symbol M or a literal symbol L. If the number of match symbols M included in the dictionary-compressed symbol string 32 of one cycle is 0, the number of literal symbols L included therein is one or more. Similarly, if the number of literal symbols L included in the dictionary-compressed symbol string 32 of one cycle is 0, the number of match symbols M included in the dictionary-compressed symbol string 32 of one cycle is one or more.

The literal/match separation circuit 102 determines whether each dictionary-compressed symbol in the dictionary-compressed symbol string 32 is a literal symbol or a match symbol. If the literal/match separation circuit 102 determines the dictionary-compressed symbol as a literal symbol, the literal/match separation circuit 102 outputs the dictionary-compressed symbol determined as the literal symbol to the decoding circuit 108. If the literal/match separation circuit 102 determines the dictionary-compressed symbol as a match symbol, the literal/match separation circuit 102 outputs the dictionary-compressed symbol determined as the match symbol to the dictionary assignment circuit 104. That is, the literal/match separation circuit 102 separates the dictionary-compressed symbols into literal symbols and match symbols. The literal/match separation circuit 102 outputs the literal symbols to the decoding circuit 108 and outputs the match symbols to the dictionary assignment circuit 104.

The dictionary assignment circuit 104 determines which dictionary is referred to in order to decompress a match symbol, that is, which dictionary is assigned to refer to a match symbol. Based on a result of the determination, the dictionary assignment circuit 104 rearranges the match symbols in the match symbol string of one cycle output from the literal/match separation circuit 102. The dictionary assignment circuit 104 outputs a match symbol string of the rearranged match symbols to the dictionary reference circuit 106. The size of the neighborhood dictionaries (second dictionary 110-2 to Nth dictionary 110-N) is smaller than that of the full-size dictionary (first dictionary 110-1). Therefore, a literal symbol corresponding to a match symbol having a large offset may not be stored in the neighborhood dictionaries 110-2 to 110-N. That is, a match symbol having a large offset cannot be decompressed even if the neighborhood dictionaries 110-2 to 110-N are referred to.

The dictionary reference circuit 106 recognizes which dictionary is assigned to the match symbols included in the input match symbol string according to the order of the match symbols. The dictionary reference circuit 106 recognizes that the full-size dictionary 110-1 is assigned to the first match symbol of the match symbol string of one cycle. The dictionary reference circuit 106 recognizes that the neighborhood dictionaries 110-2 to 110-N are assigned to the second and subsequent match symbols.

Thus, the dictionary assignment circuit 104 outputs a match symbol string in which the order of match symbols M is changed so that a match symbol which cannot be decompressed without referring to the full-size dictionary 110-1 is closer to the first match symbol than a match symbol which can be decompressed even by referring to the neighborhood dictionaries 110-2 to 110-N. That is, the dictionary assignment circuit 104 compares the offset of the match symbols M with the second size that is the size of the neighborhood dictionaries 110-2 to 110-N. If the offset is larger than the second size, the match symbol is placed at the beginning of the output symbol string so as to be decompressed by referring to the full-size dictionary 110-1. Thus, match symbols M having a large offset are rearranged so as to be output to the dictionary reference circuit 106 before match symbols M having a small offset. With this rearrangement by the dictionary assignment circuit 104, the dictionary reference circuit 106 can refer to the full-size dictionary 110-1 for the match symbol whose offset is the second size or larger and can refer to the neighborhood dictionaries 110-2 to 110-N for the other match symbols.

Assume that information that can be referred to a single dictionary is only one match symbol. Therefore, in order to make the throughput satisfaction rate of data decompression 100%, for example, the number N of dictionaries 110-1 to 110-N needs to be the number of dictionary references in which dictionaries can be referred to simultaneously in the dictionary-based decompression circuit 52. This number of dictionary references is determined by the throughput required by the data decompression device 16 and the minimum match length depending on the data compression/decompression algorithm. Assume that each of the dictionaries 110-1 to 110-N can be referred to once per unit time. An example of the unit time is one cycle. That is, the dictionary-based decompression circuit 52 can decompress N dictionary-compressed symbols in one cycle if it can refer to one of the dictionaries 110-1 to 110-N simultaneously for all the match symbols in the match symbol string of one cycle.

The dictionary reference circuit 106 includes an interface for writing data to the dictionaries 110-1 to 110-N and reading data from the dictionaries 110-1 to 110-N. The dictionary reference circuit 106 thus writes each of the decompressed data items included in the decompressed data string 31B output from the decoding circuit 108 to the dictionaries 110-1 to 110-N. The dictionary reference circuit 106 receives a match symbol string from the dictionary assignment circuit 104 and refers to the first dictionary 110-1 to Nth dictionary 110-N simultaneously for a maximum of N match symbols. The dictionary reference circuit 106 subtracts an address corresponding to the offset of a match symbol from the current write address of each of the dictionaries 110-1 to 110-N. The dictionary reference circuit 106 outputs an address obtained by subtraction to each of the dictionaries 110-1 to 110-N as a reference address. Note that if the offset is defined as a negative value, the dictionary reference circuit 106 adds the address corresponding to the offset of a match symbol to the current write address of each of the dictionaries 110-1 to 110-N to obtain the reference address. The dictionary reference circuit 106 also outputs the match length of the match symbol to each of the dictionaries 110-1 to 110-N.

The dictionary reference circuit 106 reads from the dictionaries 110-1 to 110-N a plurality of literal symbols stored in a storage location corresponding to the reference address and having the match length. The dictionary reference circuit 106 outputs a plurality of items of literal data, which are read from the dictionaries 110-1 to 110-N, at the same time and in parallel to the decoding circuit 108 as a plurality of items of dictionary reference data. The dictionary reference circuit 106 outputs the match length of the match symbol with the dictionary reference data (literal symbol) corresponding to the match symbol.

Upon receiving a literal symbol input from the literal/match separation circuit 102, and dictionary reference data (literal symbol) and match length input from the dictionary reference circuit 106, the decoding circuit 108 rearranges the literal symbols and dictionary reference data (literal symbols) in the order of the literal and match symbols in the dictionary-compressed symbol string 32 of one cycle to generate the decompressed data string 31B as a result of the decompression, and outputs the decompressed data string 31B. For this reason, the decoding circuit 108 needs information representing the order of the literal and match symbols in the dictionary-compressed symbol string 32. When the literal/match separation circuit 102 separates the dictionary-compressed symbol string 32 into literal symbols and match symbols, the literal/match separation circuit 102 generates information representing a byte location of the literal symbol and a start byte location of the match symbol in one cycle and outputs the literal symbols and match symbols together with the information. The dictionary reference circuit 106 attaches the information to the dictionary reference data (literal symbol) referred to by the match symbol and outputs the dictionary reference data (literal symbol) with the information to the decoding circuit 108.

As described above, the decompressed data string 31B is written to the dictionaries 110-1 to 110-N for reference in the dictionary-based decompression process. The interface included in the dictionary reference circuit 106 is capable of writing data to and reading data from the dictionaries 110-1 to 110-N. Therefore, the decompressed data string 31B is output from the decoding circuit 108 to the dictionary reference circuit 106. The dictionary reference circuit 106 writes the decompressed data string 31B to the dictionaries 110-1 to 110-N. If the dictionary reference circuit 106 does not include an interface for writing data to the dictionaries 110-1 to 110-N, a write circuit is coupled to the decoding circuit 108 and the dictionaries 110-1 to 110-N. In this case, not the dictionary reference circuit 106 but the write circuit writes the decompressed data string 31B to the dictionaries 110-1 to 110-N.

Although not shown, the dictionary-based decompression circuit 52 includes a buffer memory.

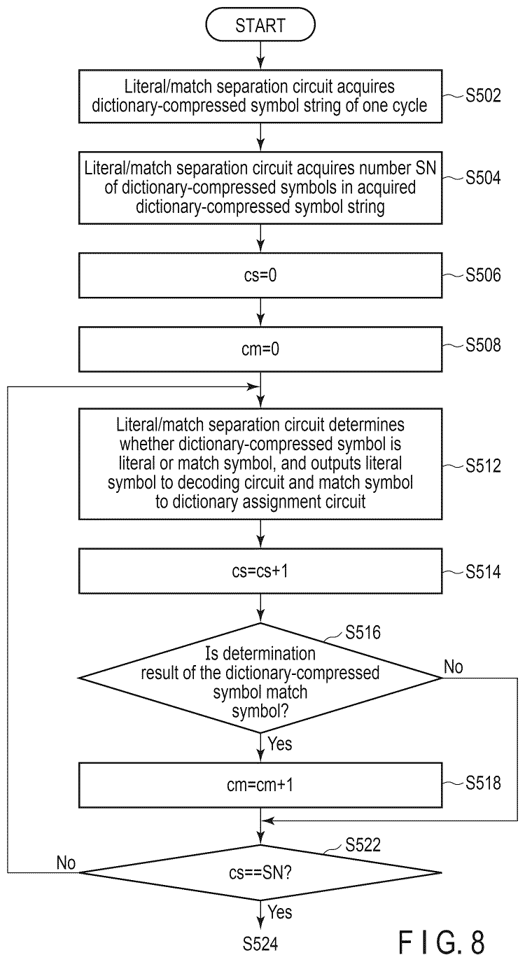

FIGS. 8 to 10 are flowcharts illustrating an example of a process of the dictionary-based decompression circuit 52.

First, the literal/match separation circuit 102 operates. The literal/match separation circuit 102 includes a symbol counter cs and a match counter “cm”.

The literal/match separation circuit 102 acquires a dictionary-compressed symbol string 32 of one cycle (step S502). The literal/match separation circuit 102 causes the acquired dictionary-compressed symbol string 32 to be stored in the buffer memory.

The literal/match separation circuit 102 acquires the number SN of dictionary-compressed symbols included in the acquired dictionary-compressed symbol string 32 (step S504). The literal/match separation circuit 102 also causes the number SN of dictionary-compressed symbols to be stored in the buffer memory.

The literal/match separation circuit 102 initializes the symbol counter cs (cs=0) (step S506).

The literal/match separation circuit 102 initializes the match counter cm (cm=0) (step S508).

The literal/match separation circuit 102 reads from the buffer memory one (a first in this case) dictionary-compressed symbol in the dictionary-compressed symbol string 32 of one cycle to determine whether the one dictionary-compressed symbol is a literal symbol or a match symbol. The literal/match separation circuit 102 outputs a dictionary-compressed symbol determined as a literal symbol to the decoding circuit 108 and outputs a dictionary-compressed symbol determined as a match symbol to the dictionary assignment circuit 104 (step S512). The literal/match separation circuit 102 also outputs the byte location of a literal symbol in the dictionary-compressed symbol string 32 of one cycle together with the literal symbol. The literal/match separation circuit 102 also outputs information representing the start byte location of a match symbol in the dictionary-compressed symbol string of one cycle together with the match symbol. The decoding circuit 108 writes the literal symbol and byte location information to the buffer memory. The dictionary assignment circuit 104 writes the match symbol and start byte location information to the buffer memory.

The literal/match separation circuit 102 increases the symbol counter cs by one (cs=cs+1) (step S514).

The literal/match separation circuit 102 determines whether the determination result of the dictionary-compressed symbol in step S512 is a match symbol (step S516).

If the determination result in step S512 is a match symbol (Yes in step S516), the literal/match separation circuit 102 increases the match counter cm by one (cm=cm+1) (step S518).

If the determination result in step S512 is not a match symbol, that is, if it is determined as a literal symbol (No in step S516) or after the match counter cm is increased by one in step S518, the literal/match separation circuit 102 determines whether the symbol counter cs is equal to the number SN of dictionary-compressed symbols in one cycle (step S522).

If the symbol counter cs is not equal to the number SN of dictionary-compressed symbols (No in step S522), the literal/match separation circuit 102 reads from the buffer memory the next dictionary-compressed symbol in the dictionary-compressed symbol string of one cycle to determine whether the next dictionary-compressed symbol is a literal symbol or a match symbol. The literal/match separation circuit 102 outputs a dictionary-based compression symbol determined as a literal symbol to the decoding circuit 108 and outputs a dictionary-compressed symbol determined as a match symbol to the dictionary assignment circuit 104 (step S512). The decoding circuit 108 writes the literal symbol and byte location information to the buffer memory. The dictionary assignment circuit 104 writes the match symbol and start byte location information to the buffer memory.

If the symbol counter cs is equal to the number SN of dictionary-compressed symbols (Yes in step S522), the literal/match separation circuit 102 sets the match counter cm as a match number MN and outputs the match number MN to the dictionary assignment circuit 104 (step S524). The dictionary assignment circuit 104 writes the match number MN to the buffer memory.

The dictionary assignment circuit 104 includes a far match counter Fcm. The far match counter Fcm indicates the number of unprocessed far match symbols. The far match symbol is a match symbol whose offset is larger than the second size. The literal symbols resulting from the decompression of the far match symbols are not stored in the neighborhood dictionaries 110-2 to 110-N, but only in the full-size dictionary 110-1. The unprocessed far match symbol is a match symbol that has not been used for dictionary reference. The dictionary assignment circuit 104 initializes the far match counter Fcm (Fcm=0) (step S526).

The dictionary assignment circuit 104 initializes the match counter cm (cm=0) (step S528).

The dictionary assignment circuit 104 reads from the buffer memory one (a first in this case) match symbol in the match symbol string output from the literal/match separation circuit 102 to determine whether the offset included in the match symbol is larger than the second size (step S532). The second size is the size of the neighborhood dictionaries 110-2 to 110-N. This determination is to determine whether the decompressed data corresponding to the match symbol is stored in the neighborhood dictionaries 110-2 to 110-N.

If the offset is larger than the second size (Yes in step S532), the dictionary assignment circuit 104 changes the location of the match symbol in the match symbol string, which is output from the dictionary assignment circuit 104, to the head (step S534). By changing the location of the match symbol in the match symbol string, the match symbol whose offset is larger than the second size is assigned to the full-size dictionary 110-1.

The dictionary assignment circuit 104 increases the far match counter Fcm by one (Fcm=Fcm+1) (step S536).

If the offset is not larger than the second size (No in step S532) or after the far match counter Fcm is increased by one in step S536, the dictionary assignment circuit 104 increases the match counter cm by one (cm=cm+1) (step S538).

The dictionary assignment circuit 104 determines whether the match counter cm is equal to the match number MN (step S542).

If the match counter cm is not equal to the match number MN (No in step S542), the dictionary assignment circuit 104 reads from the buffer memory the next match symbol in the match symbol string output from the literal/match separation circuit 102, and determines whether the offset included in the read match symbol is larger than the second size (step S532).

If the match counter cm is equal to the match number MN (Yes in step S542), the dictionary assignment circuit 104 determines whether the far match counter Fcm is larger than the number of full-size dictionaries (one in the example of FIG. 7) (step S546). In designing the dictionary-based decompression circuit 52, the number of full-size dictionaries is stored in the dictionary assignment circuit 104.

In the example of FIG. 7, if the far match counter Fcm is two or more, that is, if the match symbol string stored in the buffer memory includes two or more unprocessed match symbols having an offset larger than the second size, the determination result in step S546 is Yes. If the far match counter Fcm is larger than the number of full-size dictionaries, then two or more unprocessed match symbols having an offset larger than the second size cannot be assigned simultaneously to a single full-size dictionary 110-1. If, therefore, the far match counter Fcm is larger than the number of full-size dictionaries (Yes in step S546), the dictionary assignment circuit 104 outputs to the dictionary reference circuit 106 a match symbol at the head of the unprocessed match symbols in the match symbol string stored in the buffer memory (step S548).

The dictionary assignment circuit 104 decrements the far match counter Fcm by one (step S552).

The dictionary assignment circuit 104 issues a stall command to stall all the operations of the literal/match separation circuit 102, dictionary assignment circuit 104, and decoding circuit 108 and an operation of writing to the dictionary of the dictionary reference circuit 106 (step S554). An operation of reading from the dictionary of the dictionary reference circuit 106 (dictionary reference operation) is not stalled.

Based on the offset and match length of one match symbol received from the dictionary assignment circuit 104, the dictionary reference circuit 106 reads a literal symbol of the size of the match length from the reference address of the full-size dictionary 110-1 and then outputs the literal symbol to the decoding circuit 108 as the dictionary reference data (step S556).

After that, all the circuits of the dictionary-based decompression circuit 52 stop their operations and wait until the next cycle (step S557). In the next cycle, the dictionary assignment circuit 104 determines whether the far match counter Fcm is larger than the number of full-size dictionaries (step S546). If the far match counter Fcm is larger than the number of full-size dictionaries, steps S548, S552, S554, S556, and S557 are executed. In the example of FIG. 7, if the match symbol string stored in the buffer memory includes two or more unprocessed match symbols having an offset larger than the second size, the full-size dictionary 110-1 is referenced once per cycle for one unprocessed match symbol having an offset larger than the second size.

In the example of FIG. 7, if the far match counter Fcm is one, that is, if the match symbol string stored in the buffer memory includes one unprocessed match symbol having an offset larger than the second size, the determination result in step S546 is no. In this case, the unprocessed match symbols in the match symbol string stored in the buffer memory include (i) one match symbol located at the head and having an offset larger than the second size and (ii) no match symbol or at least one match symbol located at the second or later and having an offset that is not larger than the second size. If the far match counter Fcm is not larger than the number of full-size dictionaries (No in step S546), the dictionary assignment circuit 104 outputs to the dictionary reference circuit 106 all the unprocessed match symbols in the match symbol string stored in the buffer memory (step S558).

The dictionary reference circuit 106 simultaneously refers to the full-size dictionary 110-1 based on the first match symbol of the match symbol string received from the dictionary assignment circuit 104, and to the neighborhood dictionaries 110-2 et seq. based on the second and its subsequent match symbols. The dictionary reference circuit 106 simultaneously reads a plurality of literal symbols from the reference addresses of the dictionaries 110-1, 110-2 et seq. The dictionary reference circuit 106 simultaneously outputs the literal symbols to the decoding circuit 108 as a plurality of items of dictionary reference data (step S562).

The decoding circuit 108 assigns the dictionary reference data (literal symbols) to the decompressed data string 31B in an arrangement based on the start byte location information of the match symbol used for reading the dictionary reference data (step S564).

The decoding circuit 108 assigns the literal symbols to the decompressed data string 31B in an arrangement based on the byte location information of the lateral symbols (step S566).

The decoding circuit 108 outputs the decompressed data string 31B to which the dictionary reference data (literal symbols) and the literal symbols are assigned (step S568).

In the dictionary-based decompression circuit 52, the sizes of a plurality of dictionaries 110-1 to 110-N that store a history of decompressed data output in the past are not the same. The dictionary-based decompression circuit 52 refers to a dictionary based on the offset of a match symbol and reads decompressed data corresponding to the match symbol from the dictionary. The storage size of the dictionaries 110-1 to 110-N depends upon the maximum value of the offset. The maximum value of the offset to be supported by the dictionary-based decompression circuit 52 is determined in accordance with the compression algorithm. The number of full-size dictionaries that support the maximum value of the offset among the dictionaries 110-1 to 110-N is at least one. At least one neighborhood dictionary other than the full-size dictionary (second dictionary 110-2 to Nth dictionary 110-N in the embodiment) stores the decompressed data string 31B during a first period of time. At least one full-size dictionary (first dictionary 110-1 in the embodiment) stores decompressed data strings 31B during first and second periods. The second period is prior to the first period. The size of the neighborhood dictionary is smaller than that of the full-size dictionary. Thus, the total size of the dictionaries 110-1 to 110-N can be decreased, and the circuit scale of the dictionary-based decompression circuit 52 can be reduced, thereby improving throughput.

If the offset of a match symbol indicates data output during the second period, no neighborhood dictionary can be referred to by the match symbol. Thus, the dictionary-based decompression circuit 52 includes a dictionary assignment circuit 104. The dictionary assignment circuit 104 determines based on the offset of a match symbol whether the dictionary reference circuit 106 refers to a full-size dictionary or a neighborhood dictionary for each match symbol.

If the number of match symbols whose offset indicates data output during the second period is larger than the number of full-size dictionaries, the full-size dictionaries cannot be referred to in parallel. In this case, one of the full-size dictionaries is referred to by one match symbol in one cycle, and they are referred to in a plurality of cycles. Although a match symbol generated by data compression depends on data to be compressed, the probability that the offset of the match symbol indicates data output during the first period is higher than the probability that the offset of the match symbol indicates data output during the second period. Therefore, the dictionary-based decompression circuit 52 can reduce its circuit scale while preventing throughput from lowering.

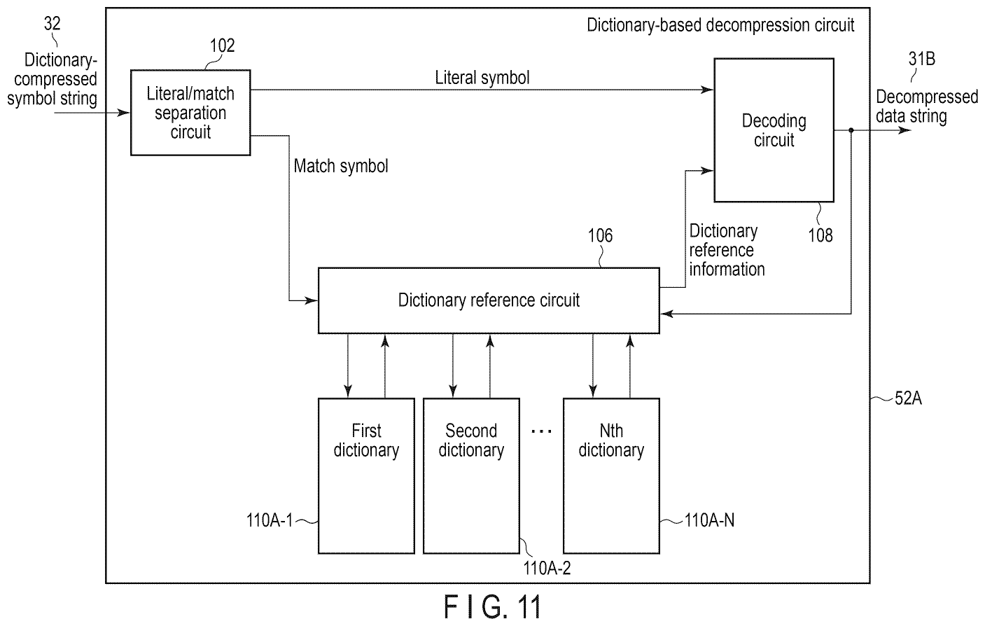

FIG. 11 is a block diagram illustrating an example of a dictionary-based decompression circuit 52A according to a comparative example. The dictionary-based decompression circuit 52A includes a plurality of dictionaries 110A-1 to 110A-N instead of the dictionaries 110-1 to 110-N and does not include the dictionary assignment circuit 104. The size of each of the dictionaries 110A-1 to 110A-N is the same as that of the first dictionary 110-1. That is, the dictionary-based decompression circuit 52A according to the comparative example includes N full-size dictionaries 110A-1 to 110A-N, and does not include a neighborhood dictionary.

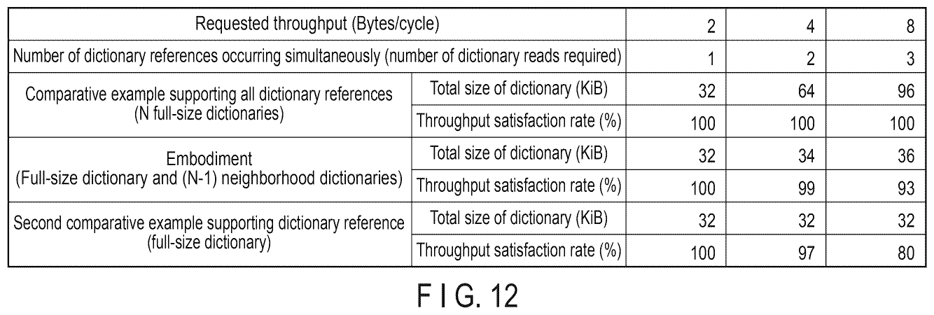

FIG. 12 is a table showing experimental results illustrating throughput satisfaction rates of the comparative example, the embodiment, and a second comparative example. The comparative example includes N full-size dictionaries, as shown in FIG. 11. The embodiment includes one full-size dictionary and (N−1) neighborhood dictionaries, as shown in FIG. 7. In the second comparative example, the number of dictionaries is one, and the one dictionary is a full-size dictionary. The second comparative example supports only the case where the number of dictionary references is one. Assume that the size of the full-size dictionary is 32 KiB and the size of the neighborhood dictionary is 2 KiB.

FIG. 12 illustrates throughput satisfaction rates in the case where the requested throughput is 2 bytes/cycle, 4 bytes/cycle, and 8 bytes/cycle. The throughput satisfaction rate is actual throughput/requested throughput. Assume here that data, which is dictionary-compressed by a compression algorithm whose minimum match length is three as the gzip algorithm, is dictionary-decompressed. For the dictionary-based compression, four data groups, Calgary corpus, Maximum Compression, Canterbury corpus, and Silesia corpus, which are generally used as benchmarks for compressed data, were used. The number of dictionary references occurring simultaneously, i.e., the number of dictionary reads required, is one, two, and three when the request throughput is 2 bytes/cycle, 4 bytes/cycle and 8 bytes/cycle, respectively.

In the second comparative example, when the requested throughput exceeds the minimum match length of 3 and reaches 4 (bytes/cycle), the number of dictionary references occurring simultaneously is 2, and the throughput satisfaction rate decreases to 97%. This trend became more pronounced as the requested throughput increases, and when the requested throughput reaches 8 (bytes/cycle), the throughput satisfaction rate decreases to 80%.

In order to achieve the required throughput, that is, to achieve a throughput satisfaction rate of 100%, it is desirable to use a comparison example that supports all the number of dictionary references occurring simultaneously. However, the comparative example causes a problem of a large circuit scale because it includes N full-size dictionaries.

In the data decompression device 52, the number of full-size dictionaries is one and the remaining dictionaries are neighborhood dictionaries of small size. If, therefore, the requested throughput increases, the increase in the total dictionary size is suppressed less than that in the comparative example 2, and the throughput satisfaction rate can be maintained at a higher value than in the comparative example 2.

### Construction Example of Dictionaries

An example of the dictionary 110 will be described.

First, an example of constructing the dictionary 110 by an SRAM (also referred to as a 1RW-SRAM) including one write/read port will be described.

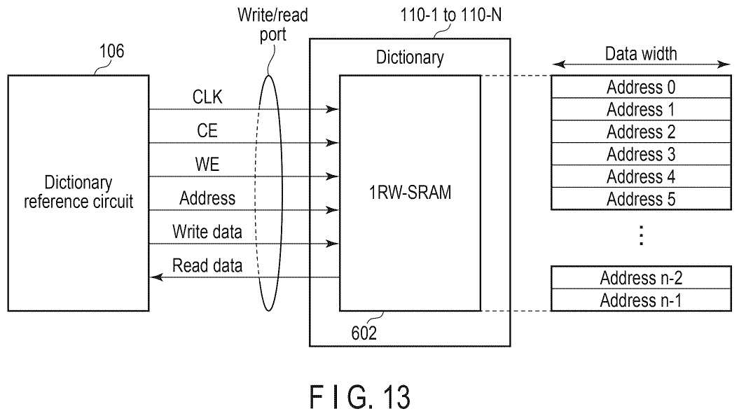

FIG. 13 is a diagram illustrating an example of the dictionaries 110-1 to 110-N. Each of the dictionaries 110-1 to 110-N includes one 1RW-SRAM 602. Each of the dictionaries 110-1 to 110-N is coupled to the dictionary reference circuit 106 via the write/read port. The write/read port includes a plurality of terminals inputting a CLK signal, a CE signal, a WE signal, an address, and write data. The write/read port further includes a terminal outputting read data. The CLK signal is a clock indicating read/write timing. The CE signal is a chip enable signal indicating that the 1RW-SRAM 602 is enabled. The WE signal is a write enable signal that designates a write operation or read operation of the 1RW-SRAM 602.

The address designates the storage location of data in the 1RW-SRAM 602. There are n storage locations, which are designated by addresses 0 to n−1. A storage location designated by one address stores a plurality of bytes of data (called a word). The data width of the word depends on throughput. If the throughput is 8 bytes/cycle, the byte width of one word is 8, and 8 bytes of data are stored in one address.

The 1RW-SRAM 602 includes one write/read port. Therefore, a write operation or read operation of the 1RW-SRAM 602 is performed once in one clock cycle.

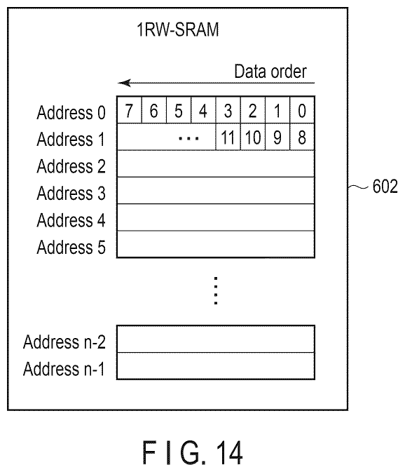

FIG. 14 is a diagram illustrating an example of reading the dictionary 110 including the 1RW-SRAM 602 according to the embodiment. Assume that the byte width of one word is 8. 8 bytes of data are stored at eight byte locations of each address. In FIG. 14, 0, 1, . . . in each address represent byte locations. The dictionary reference circuit 106 can read 8 bytes of data from an optional address in one cycle. However, the offset that defines a reference address as a read address of the dictionary is not an 8-byte unit but 1-byte unit. In this case, the reference address included in a dictionary reference command is a byte location. The dictionary reference circuit 106 needs to read 8 bytes of data from an optional byte location of an address and in this case, 8 bytes of data may not be read in one cycle. If the byte location of the read start in an address is a byte location of a multiple of 8, the dictionary reference circuit 106 can read 8 bytes of data in one cycle. If, however, the byte location of the read start is other than the byte location of a multiple of 8, the dictionary reference circuit 106 cannot read 8 bytes of data in one cycle.

Next is a description of another example of a dictionary 110 in which the dictionary reference circuit 106 can read 8 bytes of data from an optional byte location in one cycle.

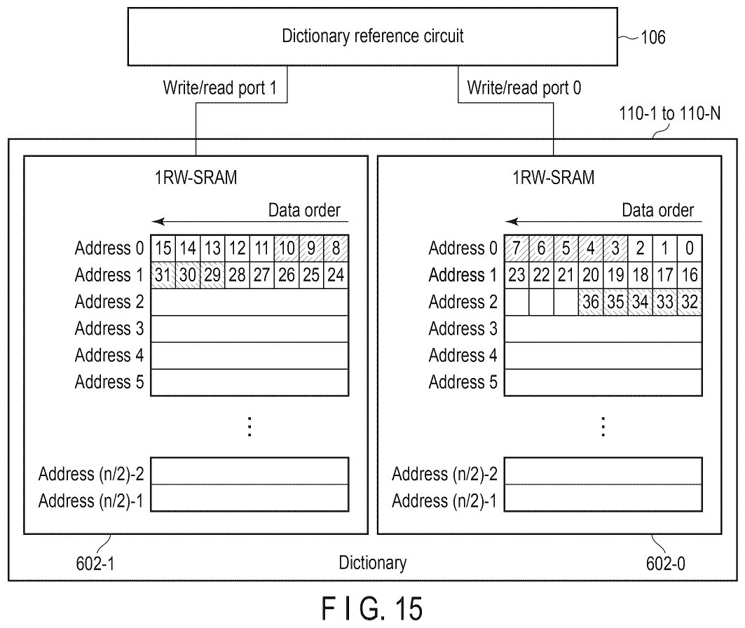

FIG. 15 is a diagram illustrating another example of the dictionaries 110-1 to 110-N according to the embodiment. Each of the dictionaries 110-1 to 110-N includes two 1RW-SRAMs 602-0 and 602-1. The 1RW-SRAM 602-0 is coupled to the dictionary reference circuit 106 via a write/read port 0. The 1RW-SRAM 602-1 is coupled to the dictionary reference circuit 106 via a write/read port 1.

The first 8 bytes of data are stored in address 0 (byte locations 0 to 7) of the 1RW-SRAM 602-0. The next 8 bytes of data are stored in address 0 (byte locations 8 to 15) of the 1RW-SRAM 602-1. Similarly, data is stored in 8 bytes alternately in the addresses of the 1RW-SRAMs 602-0 and 602-1.

When the dictionary reference circuit 106 reads data from the dictionary 110, the dictionary reference circuit 106 starts reading from one of the 1RW-SRAMs 602-0 and 602-1 in accordance with a read start byte location. If the read start byte location is included in the 1RW-SRAM 602-0, the dictionary reference circuit 106 reads data from the address Aa of the 1RW-SRAM 602-0 and then reads data from the address Ab(=Aa) of the 1RW-SRAM 602-1. If the read start byte location is included in the 1RW-SRAM 602-1, the dictionary reference circuit 106 reads data from the address Ab of the 1RW-SRAM 602-1 and then reads data from the address Aa(=Ab+1) of the 1RW-SRAM 602-0. That is, the address of the 1RW-SRAM 602 of the second read target is obtained by adding +0 or +1 to the address of the 1RW-SRAM 602 of the first read target depending on whether the read start byte location is included in either the 1RW-SRAM 602-0 or 602-1.

Assume that the read start byte location is 29 (decimal number). If the dictionary size is 2 KiB, the byte unit address is 11 bits, and the binary numeral of 29 is “00000011101”. The high-order 7 bits “0000001” of the start byte location represent the address of the 1RW-SRAM 602. The low-order 3 bits “101” represent the start byte location in the word. The eighth bit from the most significant bit indicates whether the read start byte location is included in the 1RW-SRAM 602-0 or 602-1. If the eighth bit is “1”, the read start byte location indicates that the read start byte location is included in the 1RW-SRAM 602-1. If the eighth bit is “0”, the read start byte location indicates that the read start byte location is included in the 1RW-SRAM 602-0.

The eighth bit is “1”. Therefore, the high-order 7 bits “0000001” represent address 1 of the 1RW-SRAM 602-1. The dictionary reference circuit 106 reads 3 bytes of data from the byte location 29 of address 1 of the 1RW-SRAM 602-1 and reads 5 bytes of data from the first byte location 32 of address 2 (=1+1) of the 1RW-SRAM 602-0. Thus, the dictionary reference circuit 106 reads desired 8 bytes of data from 16 bytes of data stored in two addresses of the two 1RW-SRAMs 602-0 and 602-1.

If the read start byte location is 3 (binary numeral “00000000011”), the dictionary reference circuit 106 reads 5 bytes of data from byte location 3 of address 0 of the 1RW-SRAM 602-0 and reads 3 bytes of data from first byte location 8 of address 0 (=0+0) of the 1RW-SRAM 602-1. Thus, desired continuous 8 bytes of data are read from 16 bytes of data stored in one address of the two 1RW-SRAMs 602-0 and 602-1.

If, as described above, the dictionary 110 includes the two 1RW-SRAMs 602-0 and 602-1, the dictionary reference circuit 106 can read 8 bytes of data in one cycle from an optional byte location.

Next is a description of an example of a dictionary including a multi-port SRAM.

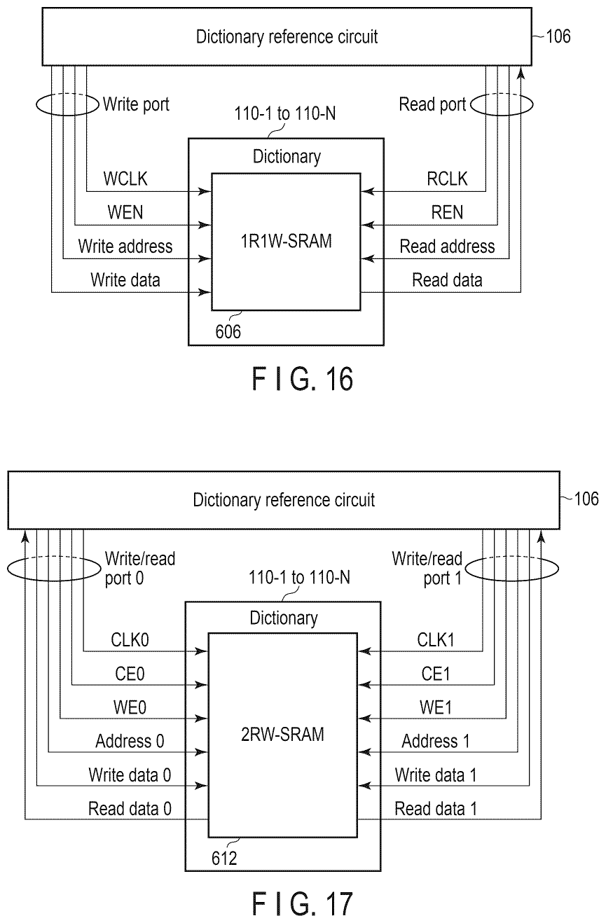

FIG. 16 is a diagram illustrating still another example of the dictionaries 110-1 to 110-N according to the embodiment. Each of the dictionaries 110-1 to 110-N includes one multi-port SRAM 606 including one write port and one read port (also referred to as a 1R1W-SRAM). The data width of the 1R1W-SRAM 606 is at least the number of bytes corresponding to the throughput. The write port includes a plurality of terminals inputting a WCLK signal, a WEN signal, a write address, and write data. The WCLK signal is a clock indicating the timing of write. The WEN signal is a write enable signal indicating that the write to the 1R1W-SRAM 606 is enabled. The write address designates a storage location in the 1R1W-SRAM 606 to which data is written. The read port includes a plurality of terminals inputting an RCLK signal, an REN signal, and a read address. The read port further includes a terminal outputting read data. The RCLK signal is a clock indicating the timing of read. The REN signal is a read enable signal indicating that the read from the 1R1W-SRAM 606 is enabled. The read address designates a storage location in the 1R1W-SRAM 606 from which data is read.

The 1R1W-SRAM 606 includes one write port and one read port. Therefore, the dictionary reference circuit 106 can perform one write operation and one read operation of the 1R1W-SRAM 606 simultaneously in one cycle. Furthermore, the clocks are divided into the WCLK signal for writing and the RCLK signal for reading. Therefore, the dictionary reference circuit 106 can perform the write and read operations of the 1R1W-SRAM 606 based on clocks of different operating frequencies.

To make it possible to read data of the number of bytes corresponding to the throughput in one cycle from an optional byte location of the dictionary 110 including the 1R1W-SRAM 606, the dictionary 110 has only to include two 1R1W-SRAMs 606 as shown in FIG. 15.

FIG. 17 is a diagram illustrating yet another example of the dictionaries 110-1 to 110-N according to the embodiment. Each of the dictionaries 110-1 to 110-N includes a multi-port SRAM 612 including two write/read ports (also referred to as a 2RW-SRAM). The data width of the 2RW-SRAM 612 is at least the number of bytes corresponding to the throughput. Each of the two write/read ports includes a plurality of terminals inputting a CLK signal, a CE signal, a WE signal, an address, and write data. Each of the two write/read ports further includes a terminal outputting read data.

The 2RW-SRAM 612 includes two write/read ports. Therefore, the dictionary reference circuit 106 can perform one write operation and one read operation of the 2RW-SRAM 612 simultaneously in one cycle, and perform two write operations simultaneously in one cycle or two read operations simultaneously in one cycle. The clocks are also divided into a CLK0 signal and a CLK1 signal for the two ports. Therefore, the dictionary reference circuit 106 can also perform the write operation or the read operation of the two ports of the 2RW-SRAM 612 based on clocks of different operating frequencies.

The 2RW-SRAM 612 can perform two read operations simultaneously in one cycle. Therefore, the dictionary reference circuit 106 can read data of the number of bytes corresponding to the throughput from an optional byte location of the dictionary 110 including the 2RW-SRAM 612 in one cycle.

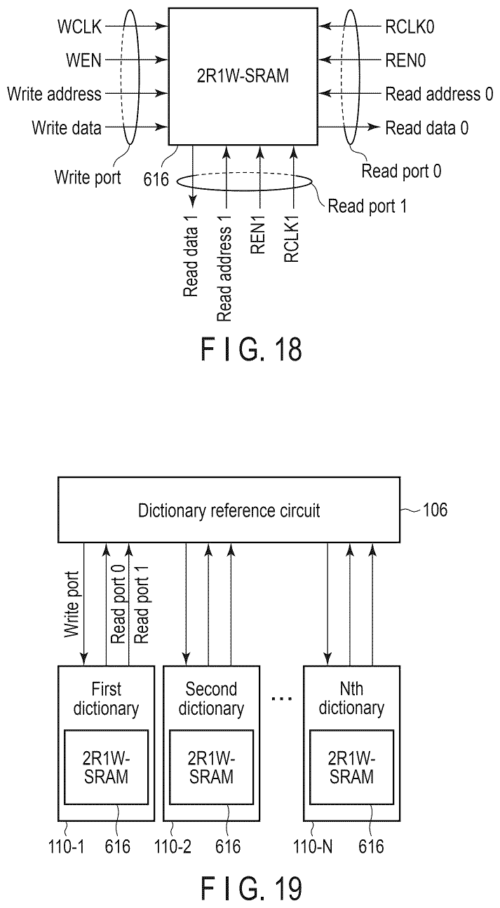

FIG. 18 is a diagram illustrating another example of the multi-port SRAM according to the embodiment. This example is an SRAM 616 including two read ports and one write port (also referred to as a 2R1W-SRAM). The data width of the 2R1W-SRAM 616 is at least the number of bytes corresponding to the throughput.

The 2R1W-SRAM 616 includes one write port and two read ports. Therefore, the dictionary reference circuit 106 can perform one write operation and two read operations simultaneously in one cycle. Furthermore, the clocks are divided into a WCLK signal, an RCLK0 signal, and an RCLK1 signal for three ports. Therefore, the dictionary reference circuit 106 can perform one write operation and two read operations based on clocks of different operating frequencies.

FIG. 19 is a diagram illustrating yet another example of the dictionaries 110-1 to 110-N according to the embodiment. Each of the dictionaries 110-1 to 110-N includes the 2R1W-SRAM 616.

The 2R1W-SRAM 616 can perform two read operations simultaneously in one cycle. Therefore, the dictionary reference circuit 106 can read data of the number of bytes corresponding to the throughput in one cycle from an optional byte location of the 2R1W-SRAM 616.

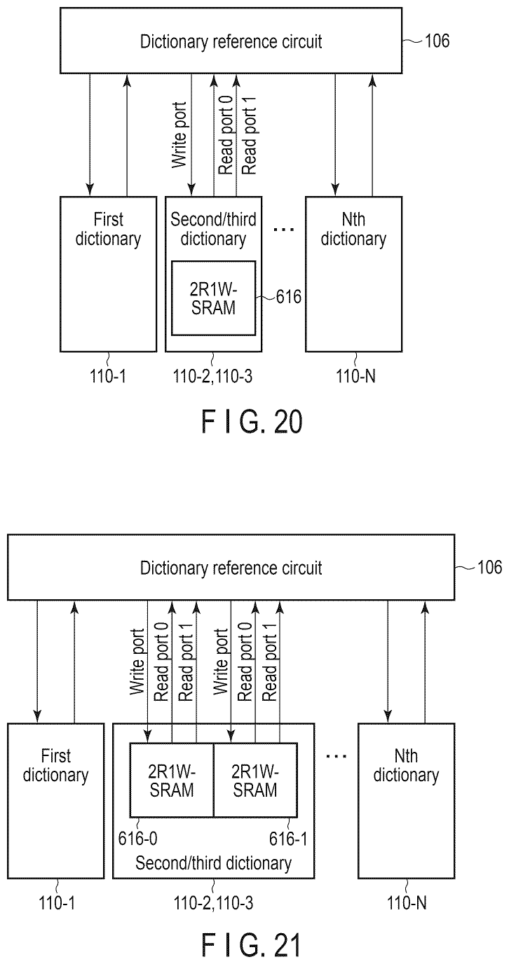

In the foregoing description, the dictionary 110 includes an SRAM dedicated to one dictionary. Using a multi-port SRAM, a plurality of dictionaries can be formed by a common SRAM. The circuit scale can be reduced. FIG. 20 is a diagram illustrating yet another example of the dictionaries 110-1 to 110-N according to the embodiment. In the example of FIG. 20, any two of the dictionaries 110-2 to 110-N, for example, the second dictionary 110-2 and the third dictionary 110-3 are formed in common by one 2R1W-SRAM 616. The second dictionary 110-2 uses a read port 0 as a read port, and the third dictionary 110-3 uses a read port 1 as a read port. The write port is used in common by the second and third dictionaries 110-2 and 110-3. The constructions of other dictionaries are optional.

Like in the example of FIG. 13, in the example of FIGS. 20, 8 bytes of continuous data cannot be read from an optional byte location because each of the second and third dictionaries 110-2 and 110-3 includes one read port.

FIG. 21 is a diagram illustrating yet another example of the dictionaries 110-1 to 110-N according to the embodiment. In this example, any two of the dictionaries 110-2 to 110-N, for example, a second dictionary 110-2 and a third dictionary 110-3 are formed in common by two 2R1W-SRAMs 616-0 and 616-1. Each of the 2R1W-SRAMs 616-0 and 616-1 is coupled to the dictionary reference circuit 106 via one write port and two read ports.

In the example of FIG. 21, each of the second and third dictionaries 110-2 and 110-3 includes two read ports. Therefore, the dictionary reference circuit 106 can read 8 bytes of continuous data from an optional byte location of each of the second and third dictionaries 110-2 and 110-3.

Next is a description of an example of constructing the dictionary 110 by a flip-flop circuit.

Although the data storage principles of a flip-flop circuit and an SRAM are almost the same, there are differences in the construction of dictionaries. The SRAM is manufactured using hard macros in which the physical arrangement and layout of internal elements is precisely designed. In the SRAM, the circuit area and power consumption are minimized by optimization. On the other hand, when a circuit equivalent to an SRAM and including a flip-flop circuit is designed, the circuit including its peripheral circuits is optimized by a CAD tool. However, the flip-flop optimization cannot optimize circuit area or power consumption to the same extent as the SRAM. An advantage of the flip-flop circuit is that a circuit can flexibly be modified. For example, when a circuit equivalent to an SRAM is designed using a flip-flop circuit, a number of write ports and a number of read ports which do not exist in a general SRAM can be mounted. For example, an SRAM including about two read ports can be formed, but an SRAM including ten read ports generally does not exist. In a dictionary including a multi-port SRAM, the type of the multi-port SRAM is defined in the design stage by the type and number of ports. However, when a dictionary equivalent to an SRAM is designed using a flip-flop circuit, the designer can add any number of read ports and write ports.

Using a flip-flop circuit, a dictionary in which a word of several byte units can be accessed by a single address as a single item of data, similar to the SRAM. The SRAM includes a read/write circuit. However, the flip-flop circuit does not include a read/write circuit. When a dictionary is designed using a flip-flop circuit, a read/write circuit is provided separately from the flip-flop circuit.

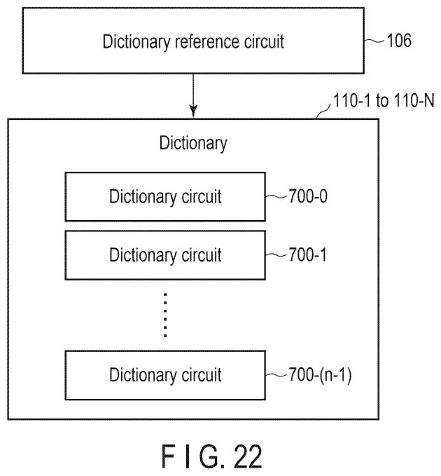

FIG. 22 is a diagram illustrating yet another example of the dictionaries 110-1 to 110-N according to the embodiment. In the example of FIG. 22, each of the dictionaries 110-1 to 110-N includes dictionary circuits 700-0, 700-1, . . . , 700-(n−1). Each of the dictionary circuits 700-0 to 700-(n−1) is assigned one address and stores data of one word (8 bytes: 64 bits). The symbol “n” is the number of addresses, that is, the number of words stored in each of the dictionaries 110-1 to 110-N, as in the case of the dictionary including the SRAM shown in FIG. 13.

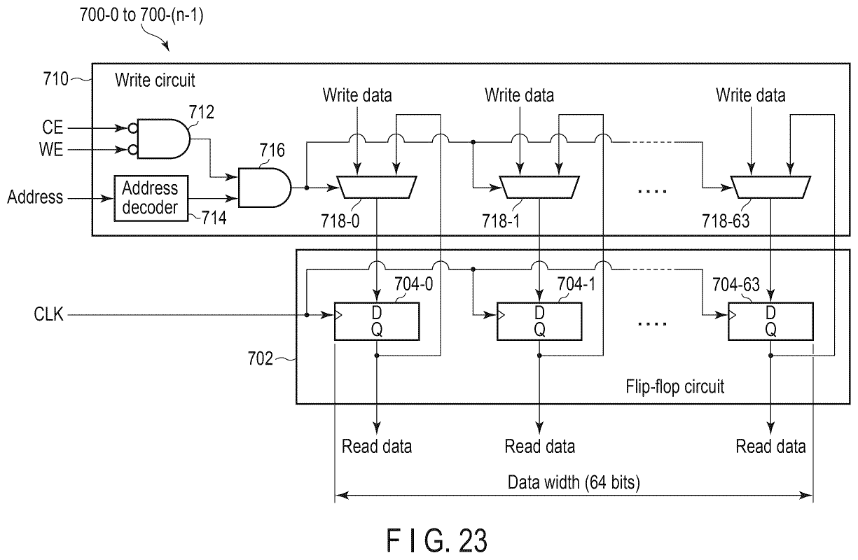

FIG. 23 is a diagram illustrating an example of write of each of the dictionary circuits 700-0 to 700-(n−1) shown in FIG. 22. Each of the dictionary circuits 700-0 to 700-(n−1) includes a write circuit 710 and a flip-flop circuit 702.

The flip-flop circuit 702 includes 64 flip-flops 704-0, 704-1, . . . , 704-63. Each of the flip-flops 704-0 to 704-63 stores 1 bit of data. The clock CLK output from the dictionary reference circuit 106 is input to the clock terminal of each of the flip-flops 704-0 to 704-63.

The write circuit 710 includes an AND gate 712, an address decoder 714, an AND gate 716, and 64 multiplexers 718-0 to 718-63. The inverted signals of CE and WE signals output from the dictionary reference circuit 106 are input to the AND gate 712. The address output from the dictionary reference circuit 106 is input to the address decoder 714. When the address designates the dictionary circuits 700-0 to 700-(n−1), the address decoder 714 outputs a “1” signal. The signals output from the AND gate 712 and address decoder 714 are input to the AND gate 716.

The signal output from the AND gate 716 is input to the control terminals of the multiplexers 718-0 to 718-63. The write data of bits 0 to 63 are input to the respective first input terminals of the multiplexers 718-0 to 718-63. The output signals Q of the flip-flops 704-0 to 704-63 are input to the respective second input terminals of the multiplexers 718-0 to 718-63. The output signals of the multiplexers 718-0 to 718-63 are input to the respective input terminals D of the flip-flops 704-0 to 704-63. Each of the multiplexers 718-0 to 718-63 outputs the write data (i.e., first inputs) when the output signal of the AND gate 716 is a “1” signal.

Like the SRAM, the write circuit 710 can control the write of one-word write data to the flip-flops 704-0 to 704-63 by an address. Thus, the flip-flop circuit 702 is also referred to as an address write type flip-flop circuit. The n write circuits 710 included in the dictionary 110 correspond to one write port.

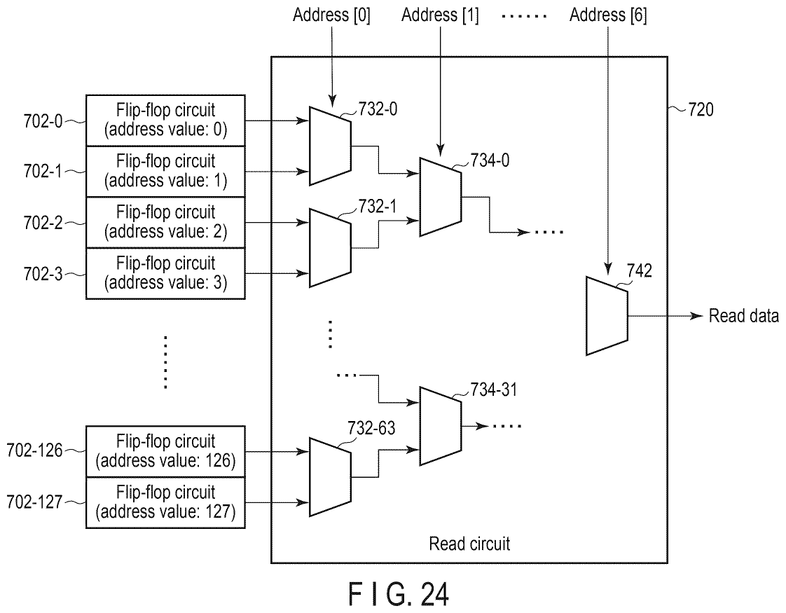

FIG. 24 is a diagram illustrating an example of read of each of the dictionary circuits 700-0 to 700-(n−1) shown in FIG. 22. To simplify the description, the address is defined as 7 bits and the total number n of addresses is defined as 128. Each of the flip-flop circuits 702-0 to 702-127 outputs the output signals Q of 64 flip-flops 704-0 to 700-63 in parallel, that is, one-word data, to a read circuit 720. The address values of the flip-flop circuits 702-0 to 702-127 are 0 to 127, respectively.

The read circuit 720 includes a multiplexer group of a plurality of stages (=log₂(n)). The number of multiplexers in each stage is half of the number of multiplexers in the previous stage. The number n is equal to 128. The number of stages in the multiplexer group is 7=log₂(128).

The first-stage multiplexer group that is supplied with the output signal of the flip-flop circuits 702 includes 64 (=n/2=128/2) multiplexers 732-0 to 732-63. The signals output from two flip-flop circuits 702 whose address values are continuous are input to one multiplexer 732 in the first-state group. The multiplexer 732 selects one of the two inputs by the address [0] of bit 0. When the address [0] is “0”, the multiplexer 732 selects the output of the flip-flop circuit 702 whose address value is small.

The second-stage multiplexer group includes 32 (=n/4=128/4) multiplexers 734-0 to 734-31. The signals output from two first-stage multiplexers 732 to which four flip-flop circuits 702 whose address values are continuous are connected, are input to the second-stage multiplexer 734. The multiplexer 734 selects one of the two inputs by the address [1] of bit 1. When the address [1] is “0”, the multiplexer 734 selects the output of the flip-flop circuit 702 whose address value is small.

Similarly, the third to seventh-stage multiplexer groups are configured. The seventh-stage (latest-stage) multiplexer group includes one (=n/128=128/128) multiplexer 742. The signals output from the two multiplexers in the sixth stage are input to the seventh-stage multiplexer 742. The multiplexer 742 selects one of the two inputs by the address [6] of bit 6. When the address [6] is “0”, the multiplexer 742 selects the output of the flip-flop circuit 702 whose address value is small.

The read circuit 720 reads data from the flip-flop circuits 702 that store words, selects one word by each bit of an address, and outputs a result of the selection as read data. The read circuit 720 corresponds to one read port.

Next is a description of an example of forming a shift register dictionary using a flip-flop circuit.

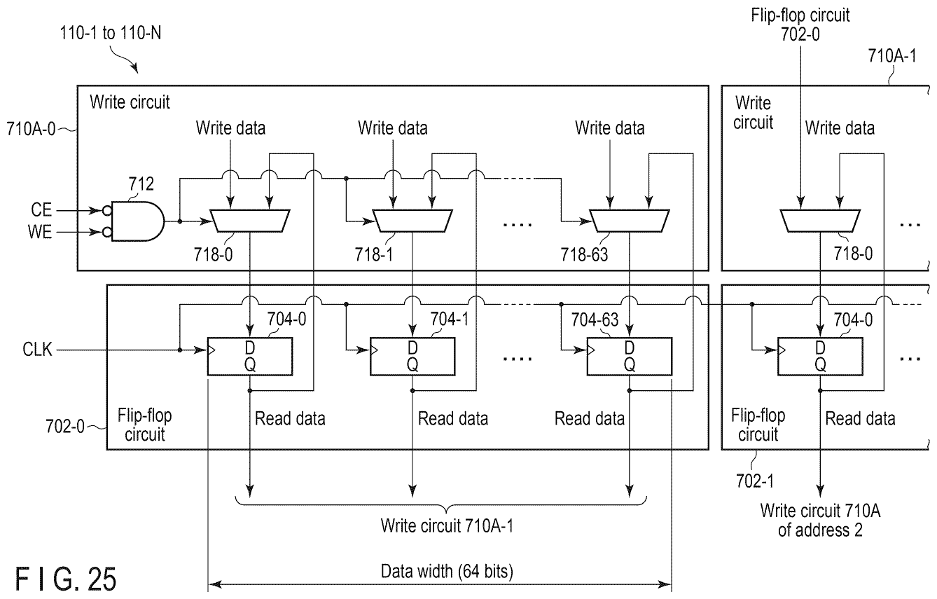

FIG. 25 is a diagram illustrating another example of write of each of the dictionaries 110-1 to 110-N shown in FIG. 22. Each of the dictionaries 110-1 to 110-N includes write circuits 710A-0, 710A-1, . . . and flip-flop circuits 702-0, 702-1, . . . for each address.

Each of the flip-flop circuits 702-0, 702-1, . . . is the same as the flip-flop circuit 702 shown in FIG. 23.

Each of the write circuits 710A-0, 710A-1 . . . corresponds to the write circuit 710 shown in FIG. 23 excluding the address decoder 714 and the AND gate 716. In FIG. 23, all bits of write data are written in parallel to the flip-flops 704-0, . . . of bits of the flip-flop circuit 702 of each address via the multiplexers 718-0, . . . of bits of the write circuit 710 of each address. In the example of FIG. 25, all bits of write data are written in parallel to the flip-flops 704-0, . . . of bits of the flip-flop circuit 702-0 of address 0 via the multiplexers 718-0, . . . of the write circuit 710A-0 of address 0. The flip-flops 704-0, . . . of bits of the flip-flop circuit 702-0 output the stored data as read data from the Q terminals when the data are written to the D terminals in synchronization with the clock CLK.

The read data of bits output from the flip-flop circuit 702-0 of address 0 are written as write data in parallel to the flip-flops 704-0, . . . of bits of the flip-flop circuit 702-1 of address 1 via the multiplexers 718-0, . . . of bits of the write circuit 710A-1 of address 1.

Similarly, the read data of each bit of the flip-flop circuit 702-i of address i is written as write data to the flip-flop 704 of each bit of the flip-flop circuit 702-(i+1) of address (i+1) via the multiplexer 718 of each bit of the write circuit 710A-(i+1) of address (i+1). In this manner, the write data is written to the flip-flop circuit 702-0 of address 0. The data stored in the flip-flop circuit 702 of each bit of address i is shifted to the flip-flop circuit 702 of the next address (i+1) in synchronization with the clock CLK.

The read circuit of the dictionaries 110-1 to 110-N shown in FIG. 25 is the same as the read circuit 720 shown in FIG. 24. In the foregoing description, an address for dictionary reference is an address obtained by subtracting the address corresponding to the offset of a match symbol from the current write address. In the case of a dictionary using a shift register flip-flop circuit 702A, the latest data is always written to address 0 and thus the current write address is address 0. Therefore, the address of dictionary reference is generated substantially based only on the offset.

Modifications of the embodiment will be described.

### Modification 1

The number of first dictionaries 110-1 is not limited to one, but may be two or more.

### Modification 2

In the embodiment, the neighborhood dictionaries 110-2 to 110-N have the same size of second size, but may have different sizes.

For example, the storage size of at least one (also referred to as a first neighborhood dictionary) of the neighborhood dictionaries 110-2 to 110-N may be set to a second size, and the storage size of at least one (also referred to as a second neighborhood dictionary) of the remaining neighborhood dictionaries may be set to a third size. The first size (storage size of the full-size dictionary 110-1) is larger than the second size which is larger than the third size.

The neighborhood dictionaries are divided into two types. Therefore, the first period of the embodiment, which is a period for writing data to the neighborhood dictionaries, is also divided into a period 1A and a period 1B. The period 1A is the latest period. The period 1B is a period prior to the period 1A. The second period of the second modification corresponds to the second period of the embodiment.

At least one item of decompressed data decompressed by the dictionary-based decompression circuit 52 during the period 1A is stored in the full-size dictionary 110-1, the first neighborhood dictionary, and the second neighborhood dictionary. The end point of the period 1A is the point at which the latest decompressed data decompressed by the dictionary-based decompression circuit 52 is stored in the full-size dictionary 110-1, the first neighborhood dictionary, and the second neighborhood dictionary.

At least one item of decompressed data decompressed by the dictionary-based decompression circuit 52 during the period 1B is stored in the first dictionary 110-1 and the first neighborhood dictionary, not in the second neighborhood dictionary. The end point of the period 1B is the start point of the period 1A.

At least one item of decompressed data decompressed by the dictionary-based decompression circuit 52 during the second period prior to the period 1B is stored in the full-size dictionary 110-1, not in the first neighborhood dictionary or the second neighborhood dictionary. The end point of the second period is the start point of the period 1B.

That is, the second neighborhood dictionary stores the decompressed data output during the period 1A. The first neighborhood dictionary stores decompressed data output during the period 1A and the period 1B. The full-size dictionary 110-1 stores decompressed data output during the period 1A, the period 1B, and the second period.

The storage of at least one item of decompressed data, which is decompressed during the period 1A, in the second neighborhood dictionary last, the storage of at least one item of decompressed data, which is decompressed during the period 1A and the period 1B, in the first neighborhood dictionary last, and the storage of at least one item of decompressed data, which is decompressed during the period 1A, the period 1B, and the second period, in the full-size dictionary 110-1 last, are executed in the same cycle.

As described above, the full-size dictionary 110-1 stores the decompressed data that is a result of decompression during the period 1A, the period 1B, and the second period. The first neighborhood dictionary stores the decompressed data as a result of decompression during the period 1A and the period 1B. The second neighborhood dictionary stores the decompressed data as a result of decompression during the period 1A.

With this modification, data read from the full-size dictionary 110-1, data read from the first neighborhood dictionary, and data read from the second neighborhood dictionary can be executed in parallel.

Alternatively, the storage sizes of the neighborhood dictionaries 110-2 to the Nth dictionary 110-N may be different. The storage size of the first dictionary 110-1 may be a first size, the storage size of the second dictionary 110-2 may be a second size, similarly. and the storage size of the Nth dictionary 110-N may be an Nth size. The first size > the second size > . . . > the Nth size.

The first dictionary 110-1 stores decompressed data that is a result of decompression during the longest period from the present time to the past. The second dictionary 110-2 stores decompressed data that is a result of decompression during the second longest period from the present time to the past. Similarly, the Nth dictionary 110-N stores the decompressed data that is a result of decompression during the shortest period from the present time to the past.

With this modification, data read from the full-size dictionary 110-1 and data read from the second dictionary 110-2 to the Nth dictionary 110-N can be executed in parallel.

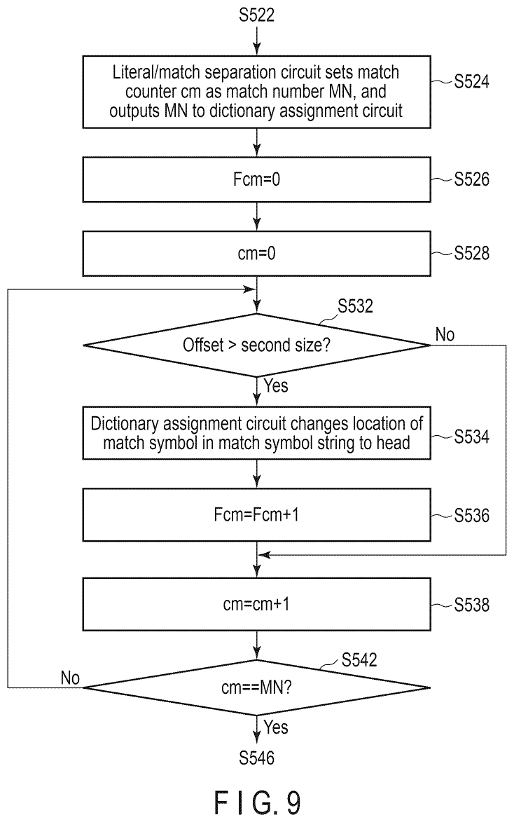

If the storage size of each of the neighborhood dictionaries 110-2 to 110-N is one of at least two sizes, the dictionary assignment circuit 104 compares the offset with a plurality of threshold sizes. For example, after step S532 in FIG. 9 in which the offset is compared with the second size, steps of comparing the offset with the third size, the fourth size, . . . are added to change a rearrangement process in step S534 to a process of arranging symbols in decreasing order of the offset.

If the distribution trend of the offset is known in advance as the trend of data to be input and the frequently appearing offset distribution is in a plurality of ranges, it is significant from the viewpoint of maintaining throughput to design a plurality of offset sizes supported by the neighborhood dictionaries in accordance with the distribution trend.

### Modification 3

The number N of dictionaries 110-1 to 110-N may be smaller than the number of references that may be made to the dictionaries simultaneously by the dictionary-based decompression circuit 52. In this case, the throughput satisfaction rate of data decompression is less than 100%. If there is no problem when the throughput satisfaction rate is less than 100%, the number N may be decreased.

### Modification 4

According to the embodiment, the dictionary reference circuit 106 refers to the first dictionary 110-1 to the Nth dictionary 110-N for the match symbols in order from the first match symbol in the input match symbol string. Therefore, the dictionary assignment circuit 104 rearranges the locations of the match symbols in the match symbol string and then transmits a result of assignment of the dictionaries to the dictionary reference circuit 106. However, the dictionary assignment circuit 104 may determine a dictionary to be referred to by a match symbol based on the offset of the match symbol, add the ID of the determined dictionary to the match symbol, and output the match symbol with the ID to the dictionary reference circuit 106. In this case, the dictionary reference circuit 106 refers to a dictionary designated by the ID regardless of the input order of the match symbols.

### Modification 5

According to the embodiment, the dictionary reference circuit 106 includes an interface for writing data to the dictionary 110. Thus, the decompressed data string 31B output from the decoding circuit 108 is input to the dictionary reference circuit 106 and written to the dictionary 110 by the dictionary reference circuit 106. However, a write circuit of the dictionary 110 may be provided separately from the dictionary reference circuit 106, and the decompressed data string 31B may be written to a plurality of dictionaries 110 by the write circuit but not through the dictionary reference circuit 106.

### Modification 6

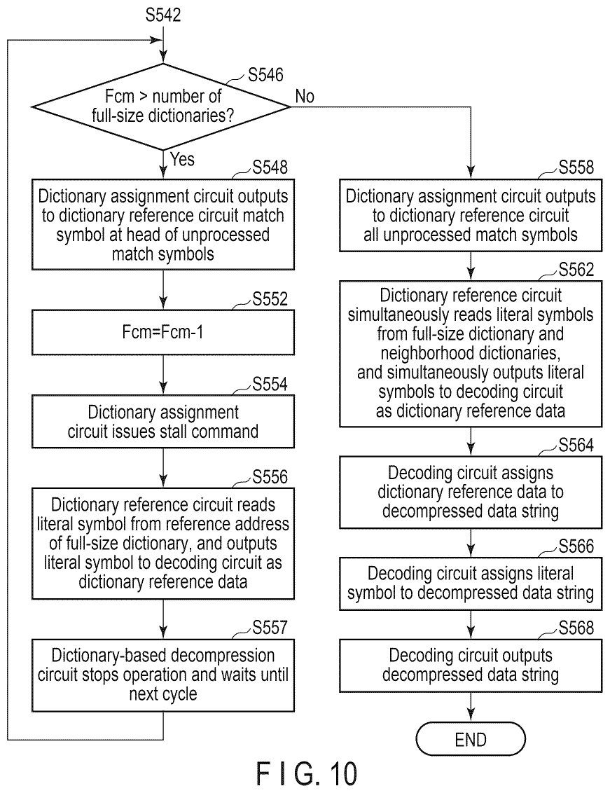

According to the embodiment, as shown in FIG. 10, if the number of unprocessed match symbols having an offset larger than the second size (the size of the neighborhood dictionary) is greater than the number of full-size dictionaries (Yes in step S546), the compressed data input in one cycle is decompressed in a plurality of cycles. Only the full-size dictionary is referred to in at least a first one cycle. The full-size dictionary and the neighborhood dictionaries are referred to simultaneously in the next cycle. Modification 6 relates to a change in the timing of reference to the neighborhood dictionaries.

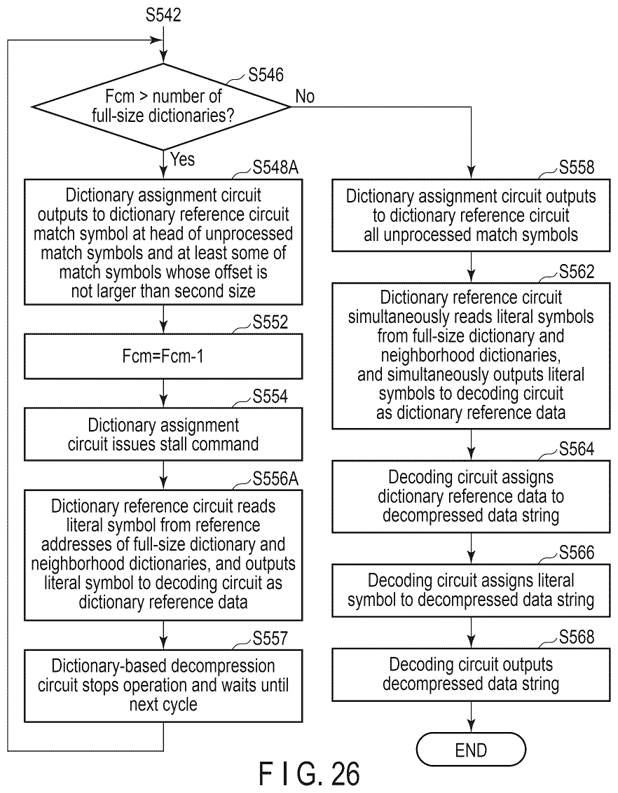

Some or all of the neighborhood dictionaries may be referred to simultaneously with the reference to the full-size dictionaries in a previous cycle (step S556) rather than in a subsequent cycle (step S562). FIG. 26 is a flowchart illustrating an example of a process of a dictionary-based decompression circuit 52 according to the modification 6. FIG. 26 is a modification to part of the process according to the embodiment shown in FIG. 10.

If the far match counter Fcm is larger than the number of full-size dictionaries (Yes in step S546), the dictionary assignment circuit 104 outputs to the dictionary reference circuit 106 a match symbol located at the head of the unprocessed match symbols in the match symbol string stored in the buffer memory and at least some of the match symbols whose offset is not larger than the second size (the size of the neighborhood dictionaries) (step S548A). The wording “at least some of the match symbols” implies “all of the match symbols”, but step S548A is directed to “some of the match symbols”.

After steps S552 and S554, based on the offset and match length of a match symbol received from the dictionary assignment circuit 104, the dictionary reference circuit 106 reads a literal symbol of the size of the match length from the reference addresses of the full-size dictionary 110-1 and the neighborhood dictionaries 110-2, . . . and outputs the literal symbol to the decoding circuit 108 as the dictionary reference data (step S556A).

If the far match counter Fcm is not larger than the number of full-size dictionaries (No in step S546), the dictionary allocation circuit 104 outputs to the dictionary reference circuit 106 all the unprocessed match symbols in the match symbol string stored in the buffer memory (step S558). All the unprocessed match symbols include match symbols whose offset is larger than the second size and match symbols whose offset is not larger than the second size. If all of the unprocessed match symbols whose offset is not larger than the second size are output to the dictionary reference circuit 106 in step S548A, all of the unprocessed match symbols in step S558 are only match symbols whose offset is larger than the second size.

The dictionary reference circuit 106 refers to the full-size dictionary 110-1 based on the first match symbol in the match symbol string received from the dictionary assignment circuit 104, refers to the neighborhood dictionaries 110-2, . . . based on the second and its subsequent match symbols, reads a plurality of literal symbols simultaneously from the reference addresses of the dictionaries 110-1, 110-2, . . . , and outputs to the decoding circuit 108 the literal symbols simultaneously as a plurality of items of dictionary reference data (step S562). If all of the unprocessed match symbols whose offset is not larger than the second size are output to the dictionary reference circuit 106 in step S548A, the neighborhood dictionaries 110-2, . . . are not referred to, but only the full-size dictionary 110-1 is referred to in step S562.

### Modification 7

Although the data compression device 15 and data decompression device 16 have been described as being implemented by hardware, at least part of each of the data compression device 15 and data decompression device 16 may be implemented by software that is executed by a processor or may be implemented by the combination of software and hardware. An example of the processor is a CPU, a digital signal processor (DSP), an application specific integrated circuit (ASIC), a graphic processing unit (GPU), a field programmable gate array (FPGA), a microcontroller, or a controller. In addition, an example of the processor is an information processing device such as a computer, a computer system in which a plurality of computers or servers perform communications with each other via a network, or a PC cluster in which a plurality of computers cooperate to execute information processing. In addition, instead of one processor executing a program for realizing a plurality of functions, a plurality of processors may realize at least some of the functions.

As described above, the data decompression device 16 makes it possible to reduce the circuit scale by limiting the number of first dictionaries that can be simultaneously referred to a small number and substituting the remaining dictionaries with neighborhood dictionaries of a small size. If the number of first dictionaries is simply reduced, the throughput is greatly decreased. However, the dictionary assignment circuit 104 can prevent the throughput from decreasing by assigning either a first dictionary or a neighborhood dictionary as a dictionary for referring to the match symbols in accordance with the offset of the match symbols.

While certain embodiments have been described, these embodiments have been presented by way of example only, and are not intended to limit the scope of the inventions. Indeed, the novel devices and methods described herein may be embodied in a variety of other forms; furthermore, various omissions, substitutions, and changes in the form according to the embodiments described herein may be made without departing from the spirit of the inventions. The accompanying claims and their equivalents are intended to cover such forms or modification as would fall within the scope and spirit of the inventions.

What is claimed is

1. A data decompression device configured to decompress a compressed data string obtained by dictionary-based compression, the compressed data string including first compressed data having a first offset, the data decompression device comprising:
a dictionary circuit including at least one first dictionary configured to store first decompressed data corresponding to the first compressed data, and at least one second dictionary configured to store the first decompressed data;
an assignment circuit configured to assign the first compressed data to at least one dictionary of the at least one first dictionary or the at least one second dictionary;
a reference circuit configured to read, using the first offset, the first decompressed data from the at least one dictionary to which the first compressed data is assigned; and
a generation circuit configured to generate a decompressed data string including the first decompressed data read by the reference circuit, wherein:
a storage size of each of the at least one first dictionary is larger than a storage size of each of the at least one second dictionary;
the first offset is configured to indicate a storage location of at least one dictionary of the at least one first dictionary or the at least one second dictionary; and
in a case where the compressed data string includes second compressed data having a second offset indicating a storage location of at least one dictionary of the at least one first dictionary or the at least one second dictionary;
the assignment circuit is configured to:
assign, based on the first offset, the first compressed data to at least one dictionary of the at least one first dictionary or the at least one second dictionary; and
assign, based on the second offset, the second compressed data to at least one dictionary of the at least one first dictionary or the at least one second dictionary, wherein the at least one dictionary to which the second compressed data is assigned is different from the at least one dictionary to which the first compressed data is assigned;
the reference circuit is configured to perform a first read and a second read in parallel, wherein
during the first read, the reference circuit is configured to read the first decompressed data using the first offset from the at least one dictionary to which the first compressed data is assigned, and
during the second read, the reference circuit is configured to read the second decompressed data corresponding to the second compressed data using the second offset from the at least one dictionary to which the second compressed data is assigned; and
the generation circuit is configured to generate the decompressed data string including the first decompressed data and the second decompressed data.

2. The data decompression device of claim 1, wherein:
in a case where the first offset indicates a storage location of the at least one first dictionary and the second offset indicates a storage location of the at least one second dictionary,
the assignment circuit is configured to assign the first compressed data to the at least one first dictionary and assign the second compressed data to the at least one second dictionary.

3. The data decompression device of claim 1, wherein:
the dictionary circuit further includes at least one third dictionary configured to store the first compressed data;
a storage size of each of the at least one second dictionary is larger than a storage size of each of the at least one third dictionary;
the first offset indicates a storage location of at least one of the at least one first dictionary, the at least one second dictionary, or the at least one third dictionary; and
in a case where the compressed data string includes second compressed data having a second offset indicating a storage location of at least one of the at least one first dictionary, the at least one second dictionary, or the at least one third dictionary, the assignment circuit is configured to:
assign, based on the first offset, the first compressed data to at least one dictionary of the at least one first dictionary, the at least one second dictionary, or the at least one third dictionary; and
assign, based on the second offset, the second compressed data to at least one dictionary of the at least one first dictionary, the at least one second dictionary, or the at least one third dictionary, wherein the at least one dictionary to which the first compressed data is assigned is different from the at least one dictionary to which the second compressed data is assigned.

4. The data decompression device of claim 3, wherein:
the at least one first dictionary is configured to store at least one item of decompressed data decompressed by the data decompression device during a first period, decompressed data decompressed by the data decompression device during a second period earlier than the first period, and decompressed data decompressed by the data decompression device during a third period earlier than the second period;
the at least one second dictionary is configured to store at least one item of decompressed data decompressed by the data decompression device during the first period and decompressed data decompressed by the data decompression device during the second period;
the at least one third dictionary is configured to store at least one item of decompressed data decompressed by the data decompression device during the first period;
first items of decompressed data which is decompressed during the first period, the second period, and the third period are written to the at least one first dictionary;
second items of decompressed data which is decompressed during the first period and the second period are written to the at least one second dictionary;
third items of decompressed data which is decompressed during the first period are written to the at least one third dictionary; and
writing a final item of the first items to the at least one first dictionary, writing a final item of the second items to the at least one second dictionary, and writing a final item of the third items to the at least one third first dictionary are performed in a cycle.

5. The data decompression device of claim 1, wherein:
each of the at least one first dictionary and the at least one second dictionary comprises a static random access memory.

6. The data decompression device of claim 1, wherein:
each of the at least one first dictionary and the at least one second dictionary comprises flip-flops.

7. The data decompression device of claim 1, wherein:
at least two dictionaries of the at least one first dictionary and the at least one second dictionary comprise an element including read ports and is configured to store same decompressed data.

8. The data decompression device of claim 1, wherein:
a storage size of each of the at least one first dictionary depends on a maximum value of the first offset.

9. The data decompression device of claim 1, wherein:
the at least one first dictionary and the at least one second dictionary are configured to store items of decompressed data decompressed during a first period in a past including a present time; and
the at least one second dictionary is configured not to store items of decompressed data decompressed during a second period earlier than the first period.

10. The data decompression device of claim 1, wherein:
at least two dictionaries of the at least one first dictionary and the at least one second dictionary comprise at least two static random access memories;
each of the at least two static random access memories includes read ports; and
the at least two static random access memories are configured to store same decompressed data.

11. The data decompression device of claim 1, wherein:
the reference circuit is configured to
write the first decompressed data to the at least one first dictionary and the at least one second dictionary; and
write the second decompressed data to the at least one first dictionary and the at least one second dictionary.

12. The data decompression device of claim 1, wherein:
in a case where the compressed data string includes items of second compressed data each having a second offset indicating a storage location of at least one dictionary of the at least one first dictionary or the at least one second dictionary, and a number of offsets which are in the first offset and the second offset, and which are larger than a threshold corresponding to a storage size of each of the at least one second dictionary is larger than a number of the at least one first dictionary,
the assignment circuit is configured to assign to the at least one first dictionary at least one item of third compressed data which is in the first compressed data and the items of second compressed data, and which has an offset larger than the threshold value, wherein a number of items of the third compressed data corresponds to a number of the at least one first dictionary; and
the reference circuit is configured to read at least one item of third decompressed data corresponding to the at least one item of third compressed data from the at least one first dictionary to which the at least one item of third compressed data is assigned.

13. The data decompression device of claim 12, wherein:
in a cycle after a cycle in which the reference circuit reads the at least one item of third decompressed data, in a case where a number of at least one item of fourth compressed data which is in the first compressed data and the items of second compressed data and has an offset larger than the threshold value, wherein the at least one item of fourth compressed data is different from the at least one item of third compressed data,
the allocation circuit is configured to
assign the at least one item of fourth compressed data to the at least one first dictionary, and
assign to the at least one second dictionary at least one item of fifth compressed data which is in the first compressed data and the items of second compressed data and has an offset equal to or smaller than the threshold value;
the reference circuit is configured to perform a first read and a second read in parallel, wherein
during the first read, the reference circuit is configured to read the at least one item of fourth decompressed data corresponding to the at least one item of fourth compressed data from the at least one first dictionary to which the at least one item of fourth compressed data is assigned, and
during the second read, the reference circuit is configured to read at least one item of fifth decompressed data corresponding to the at least one item of fifth compressed data from the at least one second dictionary to which the at least one item of fifth compressed data is assigned; and
the generation circuit is configured to generate the decompressed data string including the at least one item of third decompressed data, the at least one item of fourth decompressed data, and the at least one item of fifth decompressed data.

14. The data decompression device of claim 1, wherein:
in a case where the compressed data string includes items of second compressed data each having a second offset indicating a storage location of at least one of the at least one first dictionary or the at least one second dictionary, and a number of offsets which are in the first offset and the second offset, and which are larger than a threshold corresponding to a storage size of each of the at least one second dictionary is larger than a number of the at least one first dictionary,
the assignment circuit is configured to
assign to the at least one first dictionary at least one item of third compressed data which is in the first compressed data and the items of second compressed data and has an offset larger than the threshold value, wherein a number of items of the third compressed data corresponds to a number of the at least one first dictionary, and
assign to the at least one second dictionary at least a part of items of compressed data having an offset not larger than the threshold value; and
the reference circuit is configured to
read the at least one item of third decompressed data corresponding to the at least one item of third compressed data from the at least one first dictionary to which the at least one item of third compressed data is assigned, and
read at least one item of fourth decompressed data corresponding to the items of compressed data having the offset not larger than the threshold from the at least one second dictionary to which the at least a part of items of compressed data having the offset not larger than the threshold is assigned.

15. The data decompression device of claim 1, wherein the reference circuit is configured to perform a first read and a second read in parallel, wherein
during the first read, the reference circuit is configured to read the first decompressed data using an address obtained based on the first offset and a current write address from a dictionary to which the first compressed data is assigned, and
during the second read, the reference circuit is configured to read the second decompressed data using an address obtained based on the second offset and the current write address from a dictionary to which the second compressed data is assigned.

16. A memory system comprising:
a nonvolatile memory; and
a controller configured to write data to the nonvolatile memory and read data from the nonvolatile memory, wherein:
the controller comprises the data decompression device of claim 1; and
the controller is configured to write compressed data string obtained by dictionary-based compression to the nonvolatile memory.

17. The memory system of claim 16, wherein:
the controller further comprises a data compression device configured to compress an uncompressed data string into a compressed data string by the dictionary-based compression.

18. A method of controlling a nonvolatile memory configured to store a compressed data string including first compressed data having a first offset obtained by dictionary-based compression, wherein the first offset indicates a storage location of at least one dictionary of at least one first dictionary or at least one second dictionary, and a storage size of each of the at least one first dictionary is larger than a storage size of each of the at least one second dictionary,
the method comprising:
reading the compressed data string from the nonvolatile memory;
assigning the first compressed data included in the read compressed data string to at least one of the at least one first dictionary or the at least one second dictionary;
in a case where the compressed data string includes second compressed data having a second offset indicating a storage location of at least one dictionary of the at least one first dictionary or the at least one second dictionary,
assigning, based on the second offset, the second compressed data to at least one dictionary of the at least one first dictionary or the at least one second dictionary, wherein the at least one dictionary to which the second compressed data is assigned is different from the at least one dictionary to which the first compressed data is assigned;
reading, in parallel, using the first offset, first decompressed data corresponding to the first compressed data from the at least one dictionary to which the first compressed data is assigned, and using the second offset, second decompressed data corresponding to the second compressed data from the at least one dictionary to which the second compressed data is assigned; and
generating a decompressed data string including the first decompressed data and the second decompressed data.

19. The method of claim 18, wherein:
in a case where the first offset indicates a storage location of the at least one first dictionary and the second offset indicates a storage location of the at least one second dictionary, the method comprises:
assigning the first compressed data to the at least one first dictionary; and
assigning the second compressed data to the at least one second dictionary.

20. The method of claim 18, wherein:
a storage size of each of the at least one second dictionary is larger than a storage size of each of the at least one third dictionary;
the first offset indicates a storage location of at least one of the at least one first dictionary, the at least one second dictionary, or at least one third dictionary;
the at least one third dictionary is configured to store the first decompressed data; and
in a case where the compressed data string includes second compressed data having a second offset indicating a storage location of at least one of the at least one first dictionary, the at least one second dictionary, or the at least one third dictionary, the method comprising:
assigning, based on the first offset, the first compressed data to at least one dictionary of the at least one first dictionary, the at least one second dictionary, or the at least one third dictionary; and
assigning, based on the second offset, the second compressed data to at least one dictionary of the at least one first dictionary, the at least one second dictionary, or the at least one third dictionary, wherein the at least one dictionary to which the first compressed data is assigned is different from the at least one dictionary to which the second compressed data is assigned.
